(19) United States
(12) Patent Application Publication
(10) Pub. No.: US 2025/0265993 A1
(43) Pub. Date: Aug. 21, 2025

(54) Display Device

(71) Applicant: LG Display Co., Ltd., Seoul (KR)

(72) Inventors: Intae Ko, Daegu (KR); KwangHyun Baek, Daegu (KR)

(21) Appl. No.: 19/010,833

(22) Filed: Jan. 6, 2025

(30) Foreign Application Priority Data
Feb. 16, 2024 (KR) 10-2024-0022545

(51) Int. Cl. G09G 3/3233; G09G 3/00; H10K 59/131

(52) U.S. Cl. CPC G09G 3/3233; G09G 3/006; H10K 59/131; G09G 2300/0819; G09G 2300/0842; G09G 2300/0861; G09G 2310/08; G09G 2320/028; G09G 2330/12; G09G 2380/10

(57) ABSTRACT

A display device comprises a substrate comprising a display area and a non-display area disposed to surround the display area; a plurality of pixels disposed in the display area of the substrate; a pad part disposed in the non-display area of the substrate and supplied with a selection signal; a connection line disposed in the non-display area of the substrate, extending in a first direction, and connected to the pad part; a selection signal pattern disposed in the non-display area of the substrate, extending in a second direction different from the first direction, and connected to the connection line; and a selection signal line disposed to extend from the non-display area to the display area of the substrate, connected to the selection signal pattern, and configured to provide the selection signal, which is supplied from the pad part, to the plurality of pixels.

### CROSS-REFERENCE TO RELATED APPLICATION

This application claims the priority of Republic of Korea Patent Application No. 10-2024-0022545 filed on Feb. 16, 2024, which is hereby incorporated by reference in its entirety.

### FIELD

The present specification relates to a display device, and more particularly, to a display device capable of controlling a viewing angle.

### BACKGROUND

As technology in modern society develops, display devices are used in various ways to provide information to users. Display devices are included in electronic signs that simply transmit visual information in one direction, as well as various electronic devices that require higher technology to confirm a user input and provide information in response to the confirmed input.

For example, display devices may be included in vehicles to provide various information to a driver and passengers of the vehicle. However, the display device of the vehicle needs to display content appropriately so as not to interfere with vehicle operations. For example, the display device needs to limit display of content that may reduce concentration on driving while the vehicle is in operation.

### SUMMARY

An object to be achieved by the present specification is to provide a display device capable of dividing a display panel into areas and freely and selectively restricting a viewing angle for each of the areas.

Another object to be achieved by the present specification is to provide a display device capable of reducing the load of a selection signal line that transmits a selection signal for controlling a viewing angle of each area.

Objects of the present disclosure are not limited to the above-mentioned objects, and other objects, which are not mentioned above, can be clearly understood by those skilled in the art from the following descriptions.

According to an embodiment of the present disclosure, there is provided a display device. The display device comprises a substrate comprising a display area and a non-display area disposed to surround the display area; a plurality of pixels disposed in the display area of the substrate; a pad part disposed in the non-display area of the substrate and supplied with a selection signal; a connection line disposed in the non-display area of the substrate, extending in a first direction, and connected to the pad part; a selection signal pattern disposed in the non-display area of the substrate, extending in a second direction different from the first direction, and connected to the connection line; and a selection signal line disposed to extend from the non-display area to the display area of the substrate, connected to the selection signal pattern, and configured to provide the selection signal, which is supplied from the pad part, to the plurality of pixels.

According to an embodiment of the present disclosure, there is provided a display device. The display device comprises a substrate comprising a display area and a non-display area disposed to surround the display area; a plurality of pixels disposed in the display area of the substrate; a pad part disposed in the non-display area of the substrate and supplied with a selection signal; a connection line disposed in the non-display area of the substrate, extending in a first direction, and connected to the pad part; a selection signal pattern disposed in the non-display area of the substrate, extending in a second direction different from the first direction, and connected to the connection line; and a plurality of selection signal lines disposed to extend from the non-display area to the display area of the substrate, connected to the selection signal pattern, and configured to provide the selection signal, which is supplied from the pad part, to the plurality of pixels, wherein the plurality of selection signal lines is disposed for each pixel row of the display area.

According to an embodiment of the present disclosure, there is provided a display device. A display device comprising a display area and a non-display area disposed to surround the display area, wherein: the display area comprises a plurality of pixels; each of the plurality of pixels comprises: a first light-emitting element emitting light of a first color, a first optical member disposed on the first light-emitting element to provide a first viewing angle range, a first transistor from which a first drive current for emitting light is supplied to the first light-emitting element, a second light-emitting element emitting light of the first color, a second optical member disposed on the second light-emitting element to provide a second viewing angle range wider than the first viewing angle range, and a second transistor from which a second drive current for emitting light is supplied to the second light-emitting element; and wherein the first and second transistor are controlled by different selection signal lines. In an example, the display area comprises a plurality of sub display areas arranged along a second direction; the non-display area comprises a plurality of selection signal pattern pairs corresponding to the plurality of sub display areas; a first selection signal pattern and a second selection signal pattern in each of the plurality of selection signal pattern pairs are separated from each other along a first direction perpendicular to the second direction; and for a first selected signal pattern pair of the plurality of selection signal pattern pairs and a pixel in a first sub display area corresponding to the first selection signal pattern pair: a first selection signal pattern of the first selection signal pattern pair is configured to receive a first selection signal and be connected to a first transistor of the pixel, via a first selection signal line, to control, based on the first selection signal, a first light-emitting element of the pixel whether to emit light, and a second selection signal pattern of the first selection signal pattern pair is configured to receive a second selection signal and be connected to a second transistor of the pixel, via a second selection signal line, to control, based on the second selection signal, a second light-emitting element of the pixel whether to emit light.

According to another embodiment of the present disclosure, there is provided a display device. A display device comprising a display area and a non-display area disposed to surround the display area, comprising: a plurality of pixels disposed in the display area; a pad part disposed in the non-display are and configured to receive a selection signal; a selection signal pattern disposed in the non-display area and connected with the pad part; and a selection signal line connected to the selection signal pattern and the plurality of pixels to provide the selection signal to the plurality of pixels.

Other detailed matters of the exemplary embodiments are included in the detailed description and the drawings.

According to the present specification, the display panel may be divided into the areas, and the drive modes of the areas may be independently controlled, such that each of the areas may be operated in the first mode in which the content is provided at a wide viewing angle, or each of the areas may be operated in the second mode in which the content is provided at a narrow viewing angle.

According to the present specification, the load of the selection signal line may be reduced by the selection signal pattern connected to the selection signal line that transmits the selection signal for controlling the viewing angle of each of the areas.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified view illustrating a display device according to an embodiment of the present specification;

FIG. 2 is a functional block diagram of the display device according to an embodiment of the present specification;

FIG. 3 is a circuit diagram illustrating an example of a pixel circuit of the display device according to an embodiment of the present specification;

FIG. 4 is a circuit diagram illustrating an example of the pixel circuit of the display device according to an embodiment of the present specification;

FIGS. 5A and 5B are waveform diagrams for explaining the pixel circuit in FIG. 4 according to an embodiment of the present specification;

FIGS. 6 and 7 are cross-sectional views of the display device according to an embodiment of the present specification;

FIG. 8 is a top plan view schematically illustrating the display device according to an embodiment of the present specification;

FIG. 9 is a top plan view of the display device according to an embodiment of the present specification;

FIG. 10 is an equivalent circuit diagram of the display device according to an embodiment of the present specification; and

FIG. 11 is a top plan view of the display device according to another embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

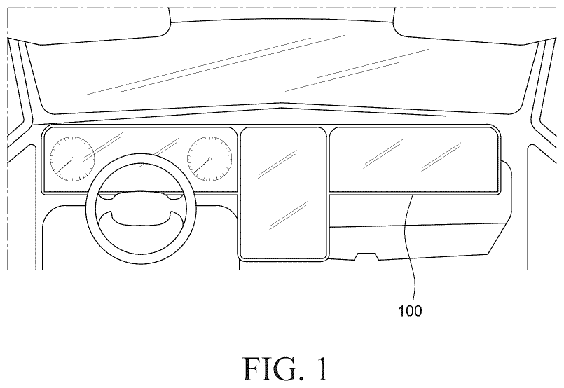

FIG. 1 is an exemplified view illustrating a display device according to an embodiment of the present specification.

With reference to FIG. 1, a display device 100 may be disposed on at least a part of a dashboard of a vehicle. The dashboard of the vehicle may include a configuration disposed at a front side of a front seat (e.g., a driver seat or a passenger seat) of the vehicle. For example, the dashboard of the vehicle may be equipped with an input configuration for manipulating various functions (e.g., an air conditioner, an audio system, and a navigation system) in the vehicle.

The display device 100 may be disposed on the dashboard of the vehicle and operate as an input part for manipulating at least some of various functions of the vehicle. The display device 100 may provide various types of information related to the vehicle, e.g., driving information of the vehicle (e.g., a current speed of the vehicle, a remaining fuel amount, and a traveling distance), information on components of the vehicle (e.g., a degree of damage to a vehicle tire), and the like.

The display device 100 may be disposed to traverse the driver seat and the passenger seat disposed as the front seat of the vehicle. Users of the display device 100 may include a driver of the vehicle, and a fellow passenger seated in the passenger seat. Both the driver and the fellow passenger in the vehicle may use the display device 100.

Only a part of the display device 100 may be illustrated in FIG. 1. The display device 100 illustrated in FIG. 1 may be illustrated as a display panel among various components included in the display device 100. Specifically, for example, the display device 100 illustrated in FIG. 1 may be illustrated as at least a part of a display area and at least a part of a non-display area of the display panel. The components, which exclude the components illustrated in FIG. 1 among the components of the display device 100, may be mounted in the vehicle (or at least a part of the vehicle).

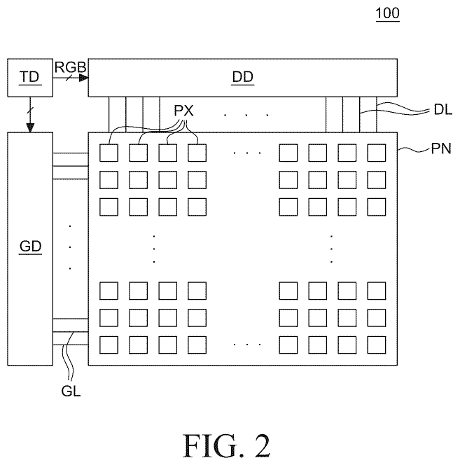

FIG. 2 is a functional block diagram of the display device according to an embodiment of the present specification.

An electroluminescent display device may be applied as the display device according to an embodiment of the present specification. An organic light-emitting diode display device, a quantum-dot light-emitting diode display device, or an inorganic light-emitting diode display device may be used as the electroluminescent display device.

With reference to FIG. 2, the display device 100 may include a display panel PN, a data drive circuit DD, a gate drive circuit GD, and a timing controller TD.

The display panel PN may create an image to be provided to the user. For example, the display panel PN may create and display images, which are to be provided to the user, through a plurality of pixels PX in which pixel circuits are disposed.

The data drive circuit DD, the gate drive circuit GD, and the timing controller TD may provide signals for operating the pixels PX through signal lines. For example, the signal lines for providing the signals for operating the pixels PX may include the plurality of data lines DL and the plurality of gate lines GL.

The plurality of data lines DL may include a plurality of lines arranged in a column direction and connected to the pixels PX disposed in one column direction. The plurality of gate lines GL may include a plurality of lines arranged in a row direction and connected to the pixels PX disposed in one row direction.

In some instances, the display device 100 may further include a power source unit (e.g., a circuit). In this case, the signal for operating the pixel PX may be provided through a power line that connects the power source unit and the display panel PN. According to the embodiment, the power source unit may provide power to the data drive circuit DD and the gate drive circuit GD. The data drive circuit DD and the gate drive circuit GD may operate on the basis of power provided from the power source unit.

For example, the data drive circuit DD may apply data signals to the pixels PX through the plurality of data lines DL, the gate drive circuit GD may apply gate signals to the pixels PX through the plurality of gate lines GL, and the power source unit may supply power voltages to the pixels PX through power voltage supply lines.

The timing controller TD may control the data drive circuit DD and the gate drive circuit GD. For example, the timing controller TD may realign digital video data, which are inputted from the outside, to fit the resolution of the display panel PN and supply the video data to the data drive circuit DD.

The data drive circuit DD may convert digital video data, which is inputted from the timing controller TD, into analog data voltage on the basis of a data control signal and supply the analog data voltage to the plurality of data lines DL.

The gate drive circuit GD may generate a scan signal and a light emission signal in response to the gate control signal. For example, the gate drive circuit GD may include a scan driver and a light emission signal driver. The scan driver may generate scan signals in a row-sequential manner to operate at least one scan line connected to each pixel row and supply the scan signals to scan lines. The light emission signal driver may generate light emission signals in a row-sequential manner to operate at least one light emission signal line connected to each pixel row and supply the light emission signals to light emission signal lines.

According to the embodiment, the gate drive circuit GD may be disposed on the display panel PN in a gate-driver-in-panel (GIP) manner. For example, the gate drive circuit GD may be divided into a plurality of gate drive circuits and respectively disposed on at least two side surface of the display panel PN.

The display panel PN may include a display area and a non-display area configured to surround the display area.

The display area of the display panel PN may include the plurality of pixels PX disposed in the row direction and the column direction. For example, the plurality of pixels PX may be disposed in an area in which the plurality of data lines DL and the plurality of gate lines GL intersect.

The plurality of pixels PX may emit light beams with different colors. For example, the plurality of pixels PX may each implement any one of three colors, e.g., blue, red, and green colors. In addition, the three pixels PX adjacent to one another in the row direction may respectively implement blue, red, and green colors. However, the present specification is not limited thereto. In some instances, the pixel PX may further implement a particular color, e.g., white.

Among the pixels PX, the pixel for implementing blue may be referred to as a blue pixel, the pixel for implementing red may be referred to as a red pixel, and the pixel for implementing green may be referred to as a green pixel. Meanwhile, according to the embodiment, the three pixels PX, which are adjacent to one another in the row direction and respectively implement blue, red, and green colors, may be referred to as subpixels for implementing the colors. Further, it may be assumed that three subpixels for implementing the colors constitute one pixel.

The plurality of pixels PX may each include first and second light-emitting elements that emit light with the same color.

The plurality of pixels PX may each include a first optical member configured to refract the light, which is emitted from the first light-emitting element, in a particular direction, and a second optical member configured to refract the light, which is emitted from the second light-emitting element, in a particular direction. For example, the first and second optical members may each be implemented as a lens. However, the embodiment of the present specification is not limited thereto.

For example, the first optical member may be disposed in an optical area configured to define a first viewing angle by providing light in a first range, and the second optical member may be disposed in an optical area configured to define a second viewing angle by providing light in a second range. The first range may correspond to a range larger than the second range. Therefore, the first and second optical members may restrict the viewing angle in each of the plurality of pixels PX.

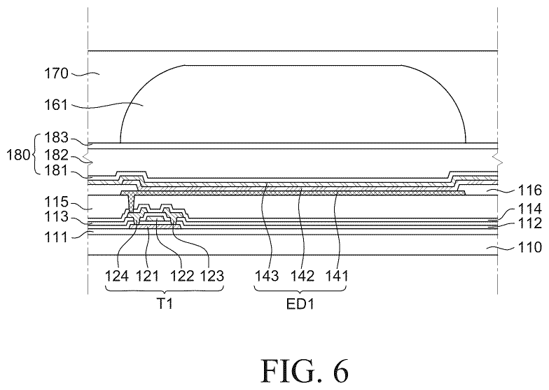

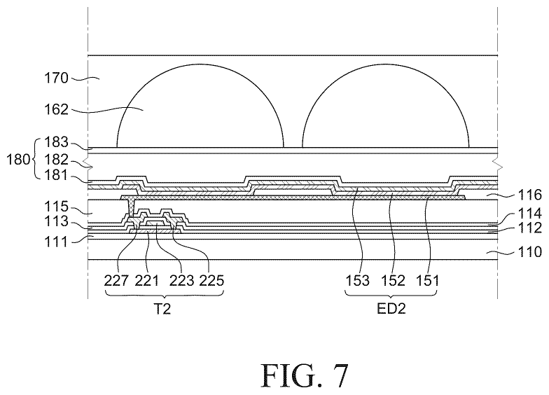

The first and second optical members will be described below in detail with reference to FIGS. 6 and 7.

The non-display area may be disposed along a periphery of the display area. Various constituent elements for operating the pixel circuit disposed in the pixel PX may be disposed in the non-display area. For example, at least a part of the gate drive circuit GD may be disposed in the non-display area. The non-display area may be referred to as a bezel area.

When the display panel PN is used for the vehicle described with reference to FIG. 1, a visual field of at least some areas of the display panel PN is required to be restricted in response to the user's needs. For example, the image, which is displayed in the area that provides the entertainment function, seat information, and the like for the fellow passenger seated in the passenger seat in the display area of the display panel PN, may hinder the driver who drives the vehicle. Therefore, the visual field of the image displayed in the corresponding area may sometimes be required to be restricted in response to the user's needs.

Therefore, the pixels PX included in the display panel PN may each be operated in a first or second mode depending on a drive mode. For example, in case that the pixel PX operates in the first mode, the first light-emitting element included in the pixel PX may emit light in response to a selection signal, and the light emitted from the first light-emitting element is provided in the first range through the first optical member, such that the first viewing angle, e.g., a wide viewing angle may be defined. In addition, in case that the pixel PX operates in the second mode, the second light-emitting element included in the pixel PX may emit light in response to a selection signal, and the light emitted from the second light-emitting element may be provided in the second range through the second optical member, such that the second viewing angle, e.g., a narrow viewing angle may be defined. In this case, the first mode may correspond to a mode in which the corresponding pixel PX is controlled in a wide visual field mode (share mode), and the second mode may correspond to a mode in which the corresponding pixel PX is operated in a narrow visual field mode (private mode).

Meanwhile, the display device 100 may divide the display panel PN into areas and independently control the drive modes of the areas. For example, the display device 100 may independently operate the plurality of areas of the display panel PN in the first mode in which the content is provided at a wide viewing angle or in the second mode in which the content is provided at a narrow viewing angle. In this case, in order to control the plurality of pixels PX, which are respectively disposed in the plurality of areas of the display panel PN, in the same drive mode, it is necessary to provide the same selection signal to the plurality of pixels PX disposed in the corresponding areas. Therefore, the same selection signal line may be connected to the plurality of pixels PX disposed in the corresponding areas and disposed in the corresponding areas. In this case, because the selection signal is provided to the plurality of pixels PX disposed in all the corresponding areas through a single line, an RC delay may occur.

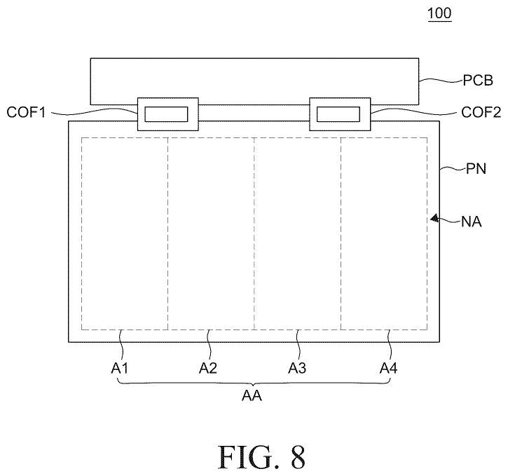

Therefore, the display device 100 according to an embodiment of the present specification may minimize or at least reduce the RC delay of the selection signal line for providing the selection signal through the selection signal pattern connected to the selection signal line. This will be described below in detail with reference to FIGS. 8 to 11.

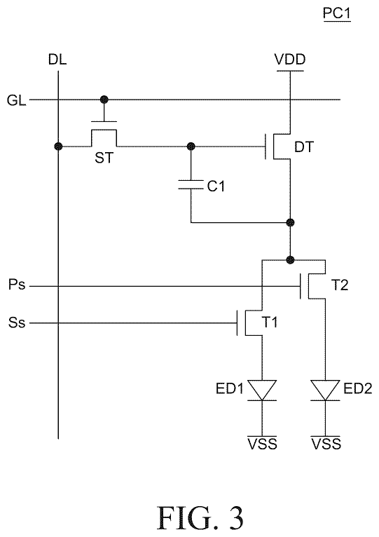

FIG. 3 is a circuit diagram illustrating an example of the pixel circuit of the display device according to an embodiment of the present specification.

Meanwhile, a first pixel circuit PC1 illustrated in FIG. 3 represents one embodiment of the pixel circuit corresponding to each of the plurality of pixels PX included in the display device 100 described with reference to FIG. 2.

With reference to FIG. 3, the first pixel circuit PC1 may include a driving transistor DT, a switching transistor ST, a first capacitor C1, a first transistor T1, a second transistor T2, and a plurality of light-emitting elements ED1 and ED2.

The driving transistor DT and the first capacitor C1 may be connected to the switching transistor ST. The first electrode of the driving transistor DT may be connected to a high-potential power line configured to provide a high-potential power voltage VDD.

The switching transistor ST may be connected to the gate line GL and supplied with the gate signal. The switching transistor ST may be turned on or off by the gate signal. A first electrode of the switching transistor ST may be connected to the data line DL. In this case, the data voltage may be supplied to a gate electrode of the driving transistor DT through the switching transistor ST on the basis that the switching transistor ST is turned on.

The first capacitor C1 may be disposed between the gate electrode and a second electrode of the driving transistor DT. The first capacitor C1 may maintain a signal applied to the gate electrode of the driving transistor DT, for example, maintain the data voltage for one frame.

The first transistor T1 may create a current path for a first drive current passing through a first light-emitting element ED1, and the second transistor T2 may create a current path for a second drive current passing through a second light-emitting element ED2.

The first transistor T1 may be disposed between the driving transistor DT and the first light-emitting element ED1, and a gate electrode of the first transistor T1 may be connected to a first selection signal line configured to provide a first selection signal Ss. When the pixel PX to which the first pixel circuit PC1 is applied operates in the first mode that is the wide visual field mode, the first selection signal Ss may be supplied to the gate electrode of the first transistor T1, such that the first transistor T1 may be turned on. Therefore, the current path for the first drive current passing through the first light-emitting element ED1 is formed, such that the first light-emitting element ED1 may emit light. Meanwhile, the first transistor T1 may be referred to as a first light emission control transistor configured to control the light emission from the first light-emitting element ED1.

The second transistor T2 may be disposed between the driving transistor DT and the second light-emitting element ED2, and a gate electrode of the second transistor T2 may be connected to a second selection signal line configured to provide a second selection signal Ps. When the pixel PX to which the first pixel circuit PC1 is applied operates in the second mode that is the narrow visual field mode, the second selection signal Ps may be supplied to the gate electrode of the second transistor T2, such that the second transistor T2 may be turned on. Therefore, the current path for the second drive current passing through the second light-emitting element ED2 is formed, such that the second light-emitting element ED2 may emit light. Meanwhile, the second transistor T2 may be referred to as a second light emission control transistor configured to control the light emission from the second light-emitting element ED2.

The first light-emitting element ED1 may be connected between the first transistor T1, which is turned on or off by the first selection signal Ss, and a low-potential power line configured to provide a low-potential power voltage VSS. The second light-emitting element ED2 may be connected between the second transistor T2, which is turned on or off by the second selection signal Ps, and the low-potential power line configured to provide the low-potential power voltage VSS.

In this case, the first light-emitting element ED1 or the second light-emitting element ED2 may be connected to another component of the first pixel circuit PC1, e.g., the driving transistor DT by the first transistor T1 or the second transistor T2 that is turned on in accordance with the drive mode. For example, the first light-emitting element ED1 may be connected to the driving transistor DT through the first transistor T1, which is turned on in the first mode, and provide the light at the wide viewing angle, which is the first viewing angle, in the first mode, i.e., the wide visual field mode by the first drive current. In addition, the second light-emitting element ED2 may be connected to the driving transistor DT through the second transistor T2, which is turned on in the second mode, and provide the light at the narrow viewing angle, which is the second viewing angle, in the second mode, i.e., the narrow visual field mode by the second drive current. In this case, the drive mode may be determined in case that a condition, which is designated by the user's input or designated in advance, is satisfied.

The plurality of transistors DT, ST, T1, and T2 in FIG. 3 may include at least one of oxide semiconductors such as amorphous silicon, polycrystalline silicon, and IGZO. The first or second electrode of the transistor may be a source electrode or a drain electrode. For example, the first electrode may be a source electrode, or the second electrode may be a drain electrode. As another example, the first electrode may be a drain electrode, and the second electrode may be a source electrode.

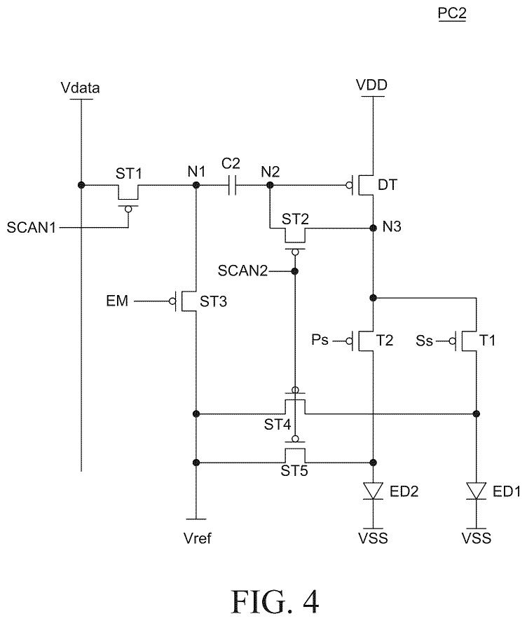

FIG. 4 is a circuit diagram illustrating an example of the pixel circuit of the display device according to an embodiment of the present specification.

Meanwhile, a second pixel circuit PC2 illustrated in FIG. 4 represents another embodiment of the pixel circuit corresponding to each of the plurality of pixels PX included in the display device 100 described with reference to FIG. 2.

With reference to FIG. 4, at least some of the plurality of transistors included in the second pixel circuit PC2 may each be an n-type transistor or a p-type transistor. In the case of the p-type transistor, a low-level voltage of each of the driving signals may mean a voltage that turns on the TFT, and a high-level voltage of each of the driving signals may mean a voltage that turns off the TFTs.

In this case, the low-level voltage may correspond to a predesignated voltage lower than the high-level voltage. For example, the low-level voltage may include a voltage corresponding to a range of −8 V to −12 V. The high-level voltage may correspond to a predesignated voltage higher than the low-level voltage. For example, the high-level voltage may include a voltage corresponding to a range of 12 V to 16 V. According to the embodiment, the low-level voltage may have a smaller value than the high-level voltage.

The second pixel circuit PC2 may include the driving transistor DT, a plurality of switching transistors ST1, ST2, ST3, ST4 and ST5, a second capacitor C2, the first transistor T1, the second transistor T2, and the plurality of light-emitting elements ED1 and ED2.

The driving transistor DT may control the drive current applied to the first light-emitting element ED1 and the second light-emitting element ED2 in accordance with a source-gate voltage.

The driving transistor DT may include a source electrode connected to the high-potential power line, which provides the high-potential power voltage VDD, a gate electrode connected to a second node N2, and a drain electrode connected to a third node N3.

A first switching transistor ST1 may apply a data voltage Vdata to a first node N1 from the data line DL. The first switching transistor ST1 may include a source electrode connected to the data line DL, a drain electrode connected to the first node N1, and a gate electrode connected to a first scan signal line to which a first scan signal SCAN1 is applied. The first switching transistor ST1 may be turned on or off by the first scan signal SCAN1. Therefore, the first switching transistor ST1 may apply the data voltage Vdata from the data line DL to the first node N1 in response to the first scan signal SCAN1 at a low level, i.e., a turn-on level.

A second switching transistor ST2 may diode-connect the gate electrode and the drain electrode of the driving transistor DT. The second switching transistor ST2 may include a drain electrode connected to the second node N2, a source electrode connected to the third node N3, and a gate electrode connected to a second scan signal line to which a second scan signal SCAN2 is applied. The second switching transistor ST2 may be turned on or off by the second scan signal SCAN2. Therefore, the second switching transistor ST2 may diode-connect the gate electrode and the drain electrode of the driving transistor DT in response to the second scan signal SCAN2 at a low level, i.e., a turn-on level.

A third switching transistor ST3 may apply a reference voltage Vref to the first node N1. The third switching transistor ST3 may include a source electrode connected to a reference voltage line configured to provide the reference voltage Vref, a drain electrode connected to the first node N1, and a gate electrode connected to a light emission signal line to which a light emission signal EM is applied. The third switching transistor ST3 may be turned on or off by the light emission signal EM. Therefore, the third switching transistor ST3 may transmit the reference voltage Vref to the first node N1 in response to the light emission signal EM at a low level, i.e., a turn-on level.

A fourth switching transistor ST4 may apply the reference voltage Vref to an anode electrode of the first light-emitting element ED1. The fourth switching transistor ST4 may include a source electrode connected to the reference voltage line configured to provide the reference voltage Vref, a drain electrode connected to the anode electrode of the first light-emitting element ED1, and a gate electrode connected to the second scan signal line to which the second scan signal SCAN2 is applied. The fourth switching transistor ST4 may be turned on or off by the second scan signal SCAN2. Therefore, the fourth switching transistor ST4 may apply the reference voltage Vref to the anode electrode of the first light-emitting element ED1 in response to the second scan signal SCAN2 at a low level, i.e., a turn-on level.

A fifth switching transistor ST5 may apply the reference voltage Vref to an anode electrode of the second light-emitting element ED2. The fifth switching transistor ST5 may include a source electrode connected to the reference voltage line configured to provide the reference voltage Vref, a drain electrode connected to the anode electrode of the second light-emitting element ED2, and a gate electrode connected to the second scan signal line to which the second scan signal SCAN2 is applied. The fifth switching transistor ST5 may be turned on or off by the second scan signal SCAN2. Therefore, the fifth switching transistor ST5 may apply the reference voltage Vref to the anode electrode of the second light-emitting element ED2 in response to the second scan signal SCAN2 at a low level, i.e., a turn-on level.

The second capacitor C2 may include a first electrode connected to the first node N1, and a second electrode connected to the second node N2. One electrode, e.g., a second electrode of the second capacitor C2 may be connected to the gate electrode of the driving transistor DT, and another electrode, e.g., a first electrode of the second capacitor C2 may be connected to the first switching transistor ST1. The second capacitor C2 may store a predetermined voltage and maintain a predetermined voltage of the gate electrode of the driving transistor DT while any one of the first light-emitting element ED1 and the second light-emitting element ED2 emits light.

The first transistor T1 may create the current path for the first drive current passing through the first light-emitting element ED1, and the second transistor T2 may create the current path for the second drive current passing through the second light-emitting element ED2.

The first transistor T1 may be connected between the driving transistor DT and the first light-emitting element ED1, and the gate electrode of the first transistor T1 may be connected to the first selection signal line configured to provide the first selection signal Ss. When the pixel PX to which the second pixel circuit PC2 is applied operates in the first mode that is the wide visual field mode, the first selection signal Ss may be supplied to the gate electrode of the first transistor T1, such that the first transistor T1 may be turned on. Therefore, the current path for the first drive current passing through the first light-emitting element ED1 is formed, such that the first light-emitting element ED1 may emit light. Meanwhile, the first transistor T1 may be referred to as the first light emission control transistor configured to control the light emission from the first light-emitting element ED1.

The second transistor T2 may be connected between the driving transistor DT and the second light-emitting element ED2, and the gate electrode of the second transistor T2 may be connected to the second selection signal line configured to provide the second selection signal Ps. When the pixel PX to which the second pixel circuit PC2 is applied operates in the second mode that is the narrow visual field mode, the second selection signal Ps may be supplied to the gate electrode of the second transistor T2, such that the second transistor T2 may be turned on. Therefore, the current path for the second drive current passing through the second light-emitting element ED2 is formed, such that the second light-emitting element ED2 may emit light. Meanwhile, the second transistor T2 may be referred to as the second light emission control transistor configured to control the light emission from the second light-emitting element ED2.

The first light-emitting element ED1 may be connected between the first transistor T1, which is turned on or off by the first selection signal Ss, and the low-potential power line configured to provide the low-potential power voltage VSS. The second light-emitting element ED2 may be connected between the second transistor T2, which is turned on or off by the second selection signal Ps, and the low-potential power line configured to provide the low-potential power voltage VSS.

In this case, the first light-emitting element ED1 or the second light-emitting element ED2 may be connected to another component of the second pixel circuit PC2, e.g., the driving transistor DT by the first transistor T1 or the second transistor T2 that is turned on in accordance with the drive mode. For example, the first light-emitting element ED1 may be connected to the driving transistor DT through the first transistor T1, which is turned on in the first mode, and provide the light at the wide viewing angle, which is the first viewing angle, in the first mode, i.e., the wide visual field mode by the first drive current. In addition, the second light-emitting element ED2 may be connected to the driving transistor DT through the second transistor T2, which is turned on in the second mode, and provide the light at the narrow viewing angle, which is the second viewing angle, in the second mode, i.e., the narrow visual field mode by the second drive current. In this case, the drive mode may be determined in case that a condition, which is designated by the user's input or designated in advance, is satisfied.

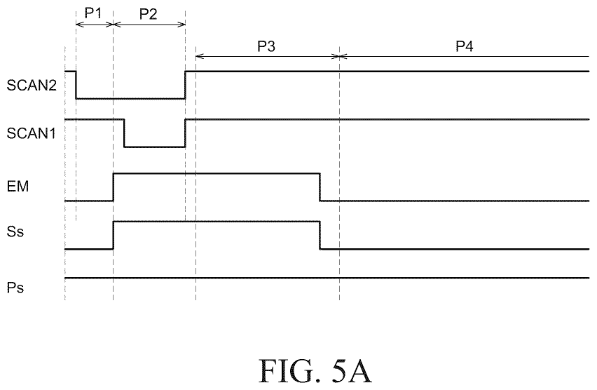

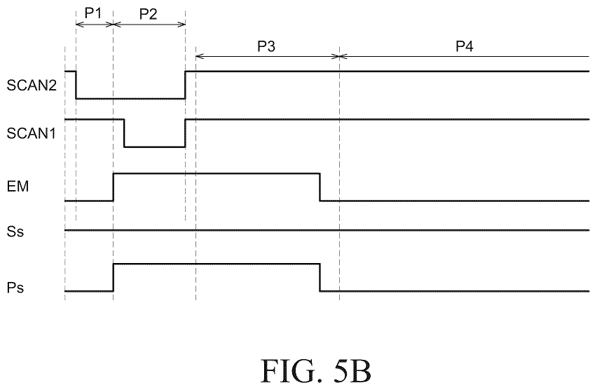

FIGS. 5A and 5B are waveform diagrams for explaining the pixel circuit in FIG. 4 according to one embodiment.

Meanwhile, FIG. 5A is a waveform diagram for explaining an example in which the pixel PX, to which the pixel circuit described with reference to FIG. 4 is applied, operates in the first mode, and FIG. 5B is a waveform diagram for explaining an example in which the pixel PX, to which the pixel circuit described with reference to FIG. 4 is applied, operates in the second mode.

With reference to FIGS. 4 to 5B, only the first light-emitting element ED1 may emit light in the first mode, and only the second light-emitting element ED2 may emit light in the second mode. In this case, as illustrated in FIG. 5A, in the first mode, the second selection signal Ps for controlling the light emission from the second light-emitting element ED2 may be outputted only at a high level, i.e., a turn-off level so that only the first light-emitting element ED1 emits light. In addition, as illustrated in FIG. 5B, in the second mode, the first selection signal Ss for controlling the light emission from the first light-emitting element ED1 may be outputted only at a high level, i.e., a turn-off level so that only the second light-emitting element ED2 emits light. Meanwhile, in the present specification, the high level may be defined as a first level.

Specifically, the first mode, which is the wide visual field mode, will be described first with reference to FIGS. 4 and 5A. During an initialization period P1, the second scan signal SCAN2 at a low level, the first selection signal Ss at a low level, and the light emission signal EM at a low level may be outputted. The second switching transistor ST2, the fourth switching transistor ST4, and the fifth switching transistor ST5 may be turned on by the second scan signal SCAN2 at a low level, the first transistor T1 may be turned on by the first selection signal Ss at a low level, and the third switching transistor ST3 may be turned on by the light emission signal EM at a low level.

The first node N1 may be initialized to the reference voltage Vref through the turned-on third switching transistor ST3. The voltage of the anode electrode of the first light-emitting element ED1 may be initialized to the reference voltage Vref through the turned-on fourth switching transistor ST4, and the voltage of the anode electrode of the second light-emitting element ED2 may be initialized to the reference voltage Vref through the turned-on fifth switching transistor ST5. The driving transistor DT may be diode-connected through the turned-on second switching transistor ST2, and the gate electrode and the drain electrode of the driving transistor DT may be short-circuited, such that the driving transistor DT may operate as a diode. The reference voltage Vref, which is transmitted to the anode electrode of the first light-emitting element ED1 through the turned-on fourth switching transistor ST4, may be transmitted to the third node N3 and the second node N2 through the turned-on first transistor T1, such that the third node N3 and the second node N2 may be initialized to the reference voltage Vref.

Next, during a sampling period P2, the first scan signal SCAN1 at a low level and the second scan signal SCAN2 at a low level may be outputted, and the first selection signal Ss at a high level may be outputted. When the light emission signal EM at a high level is outputted, the first switching transistor ST1 is turned on by the first scan signal SCAN1 at a low level at the same time when the third switching transistor ST3 is turned off, such that the data voltage Vdata may be transmitted to the first node N1. The driving transistor DT is diode-connected by the turned-on second switching transistor ST2, and the voltage difference between the high-potential power voltage VDD and the threshold voltage may be sampled and supplied to the second node N2. Meanwhile, in the present specification, the low level may be defined as a second level, and the second level may have a smaller value than the first level.

Meanwhile, during the sampling period P2, the first transistor T1 may be turned off by the first selection signal Ss at a high level.

Further, during a holding period P3, the first scan signal SCAN1 and the second scan signal SCAN2 may be outputted at a high level, and all the first switching transistor ST1, the second switching transistor ST2, the fourth switching transistor ST4, and the fifth switching transistor ST5 may be turned off. However, even though the first switching transistor ST1 is turned off, the data voltage Vdata, which is inputted during the previous period (e.g., the sampling period P2), may be maintained by the second capacitor C2.

Lastly, during a light emission period P4, the first selection signal Ss at a low level and the light emission signal EM at a low level may be outputted, and the second selection signal Ps at a high level may be outputted. The reference voltage Vref may be applied to the first node N1 through the third switching transistor ST3 turned on by the light emission signal EM at a low level. The voltage of the first node N1 may be a voltage difference between the reference voltage Vref and the data voltage Vdata, and this change in voltage may also be applied to the second node N2. A gate-source voltage of the driving transistor DT may be set to a value (Vdata-Vref+Vth) made by subtracting the reference voltage Vref from the data voltage Vdata and adding the data voltage Vdata, thereby controlling the first drive current.

Further, the first drive current is supplied from the driving transistor DT to the first light-emitting element ED1 through the first transistor T1 turned on by the first selection signal Ss at a low level, such that the first light-emitting element ED1 may emit light. However, the second selection signal Ps is outputted at a high level, and the second transistor T2 is turned off, such that the second drive current is not transmitted from the driving transistor DT to the second light-emitting element ED2. Therefore, when the pixel PX operates in the first mode, the first drive current is applied only to the first light-emitting element ED1, such that only the first light-emitting element ED1 may emit light.

Next, the second mode, which is the narrow visual field mode, will be described with reference to FIGS. 4 and 5B. The pixel circuit may operate in the second mode in substantially the same way as in the first mode, except that the first selection signal Ss and the second selection signal Ps are outputted in the opposite way to the first mode that is the wide visual field mode. That is, the first selection signal Ss may be outputted only at a high level, i.e., a turn-off level, and the second selection signal Ps may be outputted at a low level, i.e., a turn-on level during the light emission period P4 for which the second light-emitting element ED2 emits light.

Specifically, during the initialization period P1, the first scan signal SCAN1 may be outputted at a high level, and the second scan signal SCAN2 may be outputted at a low level. Further, the first selection signal Ss may be outputted at a high level, and the second selection signal Ps and the light emission signal EM may be outputted at a low level. Therefore, the second switching transistor ST2, the fourth switching transistor ST4, and the fifth switching transistor ST5 may be turned on by the second scan signal SCAN2, the second transistor T2 may be turned on by the second selection signal Ps, and the third switching transistor ST3 may be turned on by the light emission signal EM.

The first node N1 may be initialized to the reference voltage Vref through the third switching transistor ST3 turned on by the light emission signal EM, and the anode electrodes of the first and second light-emitting element ED1 and ED2 may be initialized to the reference voltage Vref by the fourth switching transistor ST4 and the fifth switching transistor ST5 turned on by the second scan signal SCAN2. The driving transistor DT may be diode-connected through the turned-on second switching transistor ST2 and operate as a diode. The reference voltage Vref, which is transmitted to the anode electrode of the second light-emitting element ED2 through the turned-on fifth switching transistor ST5, may be transmitted to the third node N3 and the second node N2 through the turned-on second transistor T2, such that the third node N3 and the second node N2 may be initialized to the reference voltage Vref.

Next, during the sampling period P2, the first scan signal SCAN1 at a low level and the second scan signal SCAN2 at a low level may be outputted, and the second selection signal Ps and the light emission signal EM may be outputted from a low level to a high level. When the light emission signal EM at a high level is outputted, the third switching transistor ST3 is turned off, the first switching transistor ST1 is turned on by the first scan signal SCAN1 at a low level, such that the data voltage Vdata may be transmitted to the first node N1. Further, the driving transistor DT is diode-connected by the turned-on second switching transistor ST2, and the voltage difference between the high-potential power voltage VDD and the threshold voltage may be sampled and supplied to the second node N2.

Meanwhile, during the sampling period P2, the second transistor T2 may be turned off by the second selection signal Ps at a high level.

Lastly, during the light emission period P4, the second selection signal Ps at a low level and the light emission signal EM at a low level may be outputted, and the first selection signal Ss at a high level may be outputted. The reference voltage Vref may be applied to the first node N1 through the third switching transistor ST3 turned on by the light emission signal EM at a low level. The voltage of the first node N1 may be a voltage difference between the reference voltage Vref and the data voltage Vdata, and this change in voltage may also be applied to the second node N2. A gate-source voltage of the driving transistor DT may be set to a value (Vdata−Vref+Vth) made by subtracting the reference voltage Vref from the data voltage Vdata and adding the data voltage Vdata, thereby controlling the second drive current.

Further, the second drive current is supplied from the driving transistor DT to the second light-emitting element ED2 through the second transistor T2 turned on by the second selection signal Ps at a low level, such that the second light-emitting element ED2 may emit light. However, the first selection signal Ss is outputted at a high level, and the first transistor T1 is turned off, such that the first drive current is not transmitted from the driving transistor DT to the first light-emitting element ED1. Therefore, when the pixel PX operates in the second mode, the second drive current is applied only to the second light-emitting element ED2, such that only the second light-emitting element ED2 may emit light.

FIGS. 6 and 7 are cross-sectional views of the display device according to an embodiment of the present specification.

FIG. 6 illustrates a pixel in which a first optical member 161 is disposed, and FIG. 7 illustrates a pixel in which a second optical member 162 is disposed.

With reference to FIGS. 6 and 7, the display device 100 according to the embodiment of the present specification may include a substrate 110, a buffer layer 111, a gate insulation layer 112, an interlayer insulation layer 113, a lower protective layer 114, an overcoating layer 115, a bank insulation layer 116, the first transistor T1, the second transistor T2, the first light-emitting element ED1, the second light-emitting element ED2, the first optical member 161, the second optical member 162, an optical member protective layer 170, and an encapsulation member 180.

The substrate 110 may include an insulating material. The substrate 110 may include a transparent material. For example, the substrate 110 may include glass or plastic.

The buffer layer 111 may be disposed on the substrate 110. The buffer layer 111 may include an insulating material. For example, the buffer layer 111 may include an inorganic insulating material such as silicon oxide (SiOx) and silicon nitride (SiNx). The buffer layer 111 may have a multilayer structure. For example, the buffer layer 111 may have a stacked structure including a layer made of silicon nitride (SiNx) and a layer made of silicon oxide (SiOx).

The buffer layer 111 may be positioned between the substrate 110 and a drive part in each of the pixels PX. The buffer layer 111 may suppress contamination caused by the substrate 110 during a process of forming the drive part. For example, the top surface of the substrate 110, which is directed toward the drive part in each of the pixels PX, may be covered by the buffer layer 111. The drive part in each of the pixels PX may be positioned on the buffer layer 111.

The gate insulation layer 112 may be disposed on the buffer layer 111. The gate insulation layer 112 may include an insulating material. For example, the gate insulation layer 112 may include an inorganic insulating material such as silicon oxide (SiO) and silicon nitride (SiN). The gate insulation layer 112 may include a material having high permittivity. For example, the gate insulation layer 112 may include a high-K material such as hafnium oxide (HfO). The gate insulation layer 112 may have a multilayer structure.

The gate insulation layer 112 may extend between semiconductor layers 121 and 221 and gate electrodes 122 and 223 of the transistors T1 and T2. For example, the gate electrodes of the switching transistor and the driving transistor may be insulated from the semiconductor layers of the switching transistor and the driving transistor by the gate insulation layer 112. The gate insulation layer 112 may cover the semiconductor layer in each of the pixels PX. The gate electrodes of the switching transistor and the driving transistor may be positioned on the gate insulation layer 112.

The interlayer insulation layer 113 may be disposed on the gate insulation layer 112. The interlayer insulation layer 113 may include an insulating material. For example, the interlayer insulation layer 113 may include an inorganic insulating material such as silicon oxide (SiO) and silicon nitride (SiN). The interlayer insulation layer 113 may extend between the gate electrodes and the source electrodes and between the gate electrodes and the drain electrodes of the driving transistor and the switching transistor. For example, the source electrodes and the drain electrodes of the driving transistor and the switching transistor may be insulated from the gate electrodes by the interlayer insulation layer 113. The interlayer insulation layer 113 may cover the gate electrodes of the switching transistor and the driving transistor. The source electrode and the drain electrode in each of the pixels PX may be positioned on the interlayer insulation layer 113. The gate insulation layer 112 and the interlayer insulation layer 113 may expose source and drain areas of each semiconductor pattern positioned in each of the pixels PX.

The lower protective layer 114 may be disposed on the interlayer insulation layer 113. The lower protective layer 114 may include an insulating material. For example, the lower protective layer 114 may include an inorganic insulating material such as silicon oxide (SiO) and silicon nitride (SiN). The lower protective layer 114 may suppress damage to the drive part caused by external moisture and impact. The lower protective layer 114 may extend along a surface of the driving transistor and a surface of the switching transistor that are opposite to the substrate 110. The lower protective layer 114 may be in contact with the interlayer insulation layer 113 outside the drive part positioned in each of the pixels PX.

The overcoating layer 115 may be disposed on the lower protective layer 114. The overcoating layer 115 may include an insulating material. The overcoating layer 115 may include a material different from the material of the lower protective layer 114. For example, the overcoating layer 115 may include an organic insulating material. The overcoating layer 115 may remove a level difference caused by the drive part in each of the pixels PX. For example, a top surface of the overcoating layer 115, which is opposite to the element substrate 110, may be a flat surface.

The first transistor T1 and the second transistor T2 may be disposed on the substrate 110. The first transistor T1 may be electrically connected between the drain electrode of the driving transistor DT and a first lower electrode 141 of the first light-emitting element ED1. The second transistor T2 may be electrically connected between the drain electrode of the driving transistor DT and a second lower electrode 151 of the second light-emitting element ED2.

The first transistor T1 may include a first semiconductor layer 121, a first gate electrode 122, a first source electrode 123, and a first drain electrode 124. The first transistor T1 may have the same structure as the switching transistor and the driving transistor. For example, the first semiconductor layer 121 may be positioned between the buffer layer 111 and the gate insulation layer 112, and the first gate electrode 122 may be positioned between the gate insulation layer 112 and the interlayer insulation layer 113. The first source electrode 123 and the first drain electrode 124 may be positioned between the interlayer insulation layer 113 and the lower protective layer 114. The first gate electrode 122 may overlap a channel area of the first semiconductor layer 121. The first source electrode 123 may be electrically connected to a source area of the first semiconductor layer 121. The first drain electrode 124 may be electrically connected to a drain area of the first semiconductor layer 121.

The second transistor T2 may include a second semiconductor layer 221, a second gate electrode 223, a second source electrode 225, and a second drain electrode 227. For example, the second semiconductor layer 221 may be positioned on the same layer as the first semiconductor layer 121, the second gate electrode 223 may be positioned on the same layer as the first gate electrode 122, and the second source electrode 225 and the second drain electrode 227 may be positioned on the same layer as the first source electrode 123 and the first drain electrode 124.

The first light-emitting element ED1 and the second light-emitting element ED2 in each of the pixels PX may be disposed on the overcoating layer 115 in the corresponding pixel PX.

The first light-emitting element ED1 may emit light with a particular color. For example, the first light-emitting element ED1 may include the first lower electrode 141, a first light-emitting layer 142, and a first upper electrode 143 sequentially stacked on the substrate 110.

The first lower electrode 141 may include an electrically conductive material. The first lower electrode 141 may include a material having high reflectance. For example, the first lower electrode 141 may include metal such as aluminum (Al) and silver (Ag). The first lower electrode 141 may have a multilayer structure. For example, the first lower electrode 141 may have a structure in which a reflective electrode, which is made of metal, is positioned between transparent electrodes made of a transparent conductive material such as ITO and IZO. The first lower electrode 141 may be electrically connected to the first drain electrode 124 of the first transistor T1 through contact holes formed through the lower protective layer 114 and the overcoating layer 115.

The first light-emitting layer 142 may create light with brightness corresponding to a voltage difference between the first lower electrode 141 and the first upper electrode 143. For example, the first light-emitting layer 142 may include an emission material layer (EML) including a light-emitting material. The light-emitting material may include an organic material, an inorganic material, or a hybrid material.

The first light-emitting layer 142 may have a multilayer structure. For example, the first light-emitting layer 142 may further include at least one of a hole injection layer (HIL), a hole transport layer (HTL), an electron transport layer (ETL), and an electron injection layer (EIL).

The first upper electrode 143 may include an electrically conductive material. The first upper electrode 143 may include a material different from the material of the first lower electrode 141. A transmittance rate of the first upper electrode 143 may be higher than a transmittance rate of the first lower electrode 141. For example, the first upper electrode 143 may be configured as a transparent electrode made of a transparent conductive material such as ITO and IZO. Therefore, in the display device 100 according to the embodiment of the present specification, the light created by the first light-emitting layer 142 may be discharged through the first upper electrode 143.

The second light-emitting element ED2 may implement the same color as the first light-emitting element ED1. The second light-emitting element ED2 may have the same structure as the first light-emitting element ED1. For example, the second light-emitting element ED2 may include the second lower electrode 151, a second light-emitting layer 152, and a second upper electrode 153 sequentially stacked on the substrate 110.

The second lower electrode 151 may correspond to the first lower electrode 141, the second light-emitting layer 152 may correspond to the first light-emitting layer 142, and the second upper electrode 153 may correspond to the first upper electrode 143. For example, the second lower electrode 151 may be formed for the second light-emitting element ED2 while having the same structure as the first lower electrode 141. The same may apply to the second light-emitting layer 152 and the second upper electrode 153. For example, the first light-emitting element ED1 and the second light-emitting element ED2 may be formed to have the same structure. However, the present specification is not limited thereto. In some instances, the first light-emitting element ED1 and the second light-emitting element ED2 may be formed to be different from each other in at least some configurations.

The second light-emitting layer 152 may be spaced apart from the first light-emitting layer 142. Therefore, in the display device according to the embodiment of the present specification, it is possible to suppress light emission caused by a leakage current.

According to the embodiment of the present specification, in the display device, only one of the first light-emitting layer 142 and the second light-emitting layer 152 may create light in accordance with the user's selection or a predesignated condition.

The second lower electrode 151 in each of the pixels PX may be spaced apart from the first lower electrode 141 in the corresponding pixel PX. For example, the bank insulation layer 116 may be disposed between the first lower electrode 141 and the second lower electrode 151 in each of the pixels PX. The bank insulation layer 116 may include an insulating material. For example, the bank insulation layer 116 may include an organic insulating material. The bank insulation layer 116 may include a material different from the material of the overcoating layer 115.

The second lower electrode 151 in each of the pixels PX may be insulated from the first lower electrode 141 in the corresponding pixel PX by the bank insulation layer 116. For example, the bank insulation layer 116 may cover an edge of the first lower electrode 141 and an edge of the second lower electrode 151 positioned in each of the pixels PX. Therefore, the display device 100 may provide the user with images in a first optical area in the pixel PX in which the first light-emitting element ED1 is positioned, or the display device 100 may provide the user with images in a second optical area in the pixel PX in which the second light-emitting element ED2 is positioned.

The first light-emitting layer 142 and the first upper electrode 143 of the first light-emitting element ED1, which is positioned in each of the pixels PX, may be stacked in a partial area of the corresponding first lower electrode 141 exposed by the bank insulation layer 116. The second light-emitting layer 152 and the second upper electrode 153 of the second light-emitting element ED2, which is positioned in each of the pixels PX, may be stacked in a partial area of the corresponding second lower electrode 151 exposed by the bank insulation layer 116. For example, in each of the pixels PX, the bank insulation layer 116 may be divided into a first light-emitting area in which light is emitted by the first light-emitting element ED1, and a second light-emitting area in which light is emitted by the second light-emitting element ED2. In each of the pixels PX, a size of the defined second light-emitting area may be smaller than a size of the defined first light-emitting area.

In each of the pixels PX, the second upper electrode 153 may be electrically connected to the first upper electrode 143 in the corresponding pixel PX. For example, a voltage, which is applied to the second upper electrode 153 of the second light-emitting element ED2 positioned in each of the pixels PX, may be equal to a voltage applied to the first upper electrode 143 of the first light-emitting element ED1 positioned in the corresponding pixel PX. The second upper electrode 153 in each of the pixels PX may include the same material as the first upper electrode 143 in the corresponding pixel PX. For example, the second upper electrode 153 in each of the pixels PX may be formed simultaneously with the first upper electrode 143 in the corresponding pixel PX. The second upper electrode 153 in each of the pixels PX may extend on the bank insulation layer 116 and be in direct contact with the first upper electrode 143 in the corresponding pixel PX. The luminance of the first optical area positioned in each of the pixels PX and the luminance of the second optical area may be controlled by a drive current generated in the corresponding pixel PX.

The encapsulation member 180 may be positioned on the first light-emitting element ED1 and the second light-emitting element ED2 in each of the pixels PX. The encapsulation member 180 may suppress damage to the light-emitting elements ED1 and ED2 caused by moisture and impact from the outside. The encapsulation member 180 may have a multilayer structure. For example, the encapsulation member 180 may include a first encapsulation layer 181, a second encapsulation layer 182, and a third encapsulation layer 183 sequentially stacked. However, the present specification is not limited thereto. The first encapsulation layer 181, the second encapsulation layer 182, and the third encapsulation layer 183 may include an insulating material. The second encapsulation layer 182 may include a material different from the material of the first encapsulation layer 181 and the third encapsulation layer 183. For example, the first encapsulation layer 181 and the third encapsulation layer 183 are inorganic encapsulation layers including an inorganic insulating material, and the second encapsulation layer 182 may include an organic encapsulation layer including an organic insulating material. Therefore, damage to the light-emitting elements ED1 and ED2 of the display device 100 caused by moisture and impact from the outside may be more effectively suppressed.

The first optical member 161 and the second optical member 162 may be disposed on the encapsulation member 180.

The first optical member 161 may be disposed on the first light-emitting element ED1. The light created by the first light-emitting element ED1 in each of the pixels PX may be discharged through the first optical member 161 disposed in the first optical area in the corresponding pixel PX. The first optical member 161 may have a shape in which at least light in one direction may not be restricted. For example, a planar shape of the first optical member 161 positioned in each of the pixels PX may be a bar shape extending in one direction.

In this case, a propagation direction of the corresponding light emitted from the first optical area in each of the pixels PX may not be limited to one direction. For example, the content (or images) provided through the first optical area in each of the pixels PX may be shared with surrounding people adjacent to the user in one direction. Therefore, the content, which is provided by the light emitted through the first optical member 161, may be provided in a first viewing angle range having a larger viewing angle than the content provided by the light emitted through the second optical member 162. For example, the content, which is provided by the light emitted through the first optical member 161, may be provided in a wide visual field mode (share mode).

The second light-emitting element ED2 may be disposed on the second optical member 162. The light created by the second light-emitting element ED2 in each of the pixels PX may be discharged through the second optical member 162 disposed in the second optical area in the corresponding pixel PX. The second optical member 162 may restrict the propagation direction, in which the light passes through the second optical member 162, to one direction and/or another direction. For example, a planar shape of the second optical member 162 positioned in each of the pixels PX may be a circular shape.

In this case, the propagation direction of the light emitted from the second optical area in each of the pixels PX may be limited to one direction and/or another direction. For example, the content (or images) provided by the second optical area in each of the pixels PX may not be shared with surrounding people adjacent to the user. Therefore, the content, which is provided by the light emitted through the second optical member 162, may be provided in a second viewing angle range having a smaller viewing angle than the content provided by the light emitted through the first optical member 161. For example, the content, which is provided by the light emitted through the second optical member 162, may be provided in a narrow visual field mode (private mode).

The first light-emitting area in each of the pixels PX may have a shape corresponding to the first optical member 161 in the corresponding pixel PX. For example, a planar shape of the first light-emitting area in each of the pixels PX may be a bar shape extending in one direction. The first optical member 161 may have a larger size than the first light-emitting area in the corresponding pixel PX. Therefore, it is possible to improve the efficiency of the light emitted from the first light-emitting area in the pixel PX.

The second light-emitting area in each of the pixels PX may have a shape corresponding to the second optical member 162 in the corresponding pixel PX. For example, a planar shape of the second light-emitting area in each of the pixels PX may be a circular shape. The second optical member 162 may have a larger size than the second light-emitting area in the corresponding pixel PX. Therefore, it is possible to improve the efficiency of the light emitted from the second light-emitting area in the pixel PX.

The optical member protective layer 170 may be positioned on the first optical member 161 and the second optical member 162 in the pixel PX. The optical member protective layer 170 may include an insulating material. For example, the optical member protective layer 170 may include an organic insulating material. A refractive index of the optical member protective layer 170 may be smaller than a refractive index of the first optical member 161 and a refractive index of the second optical member 162 positioned in each of the pixels PX. Therefore, in the display device 100 according to the embodiment of the present specification, the light, which has passed through the first optical member 161 and the second optical member 162 in each of the pixels PX, may not be reflected toward the substrate 110 because of a difference in the refractive index from the optical member protective layer 170.

FIG. 8 is a top plan view schematically illustrating the display device according to an embodiment of the present specification.

Meanwhile, for convenience of description, hereinafter, a first direction X is illustrated as a vertical direction in a plan view, and a second direction Y is illustrated as a horizontal direction in a plan view. However, this is provided for illustrative purposes only. The first direction X and the second direction Y may be variously defined.

Meanwhile, for convenience of description, FIG. 8 illustrates the display panel PN, a plurality of connection films COF1 and COF2, and a printed circuit board PCB among various constituent elements of the display device 100.

With reference to FIG. 8, the display device 100 includes the plurality of connection films COF1 and COF2, at least one printed circuit board PCB, and the display panel PN.

The plurality of connection films COF1 and COF2 may be disposed at one end of the display panel PN. For example, the plurality of connection films COF1 and COF2 may include a first connection film COF1 and a second connection film COF2 electrically connected to one end of the display panel PN. The plurality of connection films COF1 and COF2 may each be a flexible film. However, the present specification is not limited thereto.

Meanwhile, FIG. 8 illustrates that the display device 100 includes the two connection films, i.e., the first connection film COF1 and the second connection film COF2. However, this is provided for illustrative purposes only, and the embodiment of the present specification is not limited thereto. For example, the display device 100 may include one connection film or three or more connection films.

The plurality of connection films COF1 and COF2 are each a film made by disposing various types of components on a base film with flexibility and configured to supply signals to the plurality of pixels PX and the drive circuit. The plurality of connection films COF1 and COF2 may be electrically connected to the display panel PN. For example, the plurality of connection films COF1 and COF2 may supply the power voltage, the data voltage Vdata, various types of signals, and the like to the plurality of pixels PX and the drive circuit.

The data drive circuit DD, e.g., a drive IC such as a data driver IC may be disposed on the plurality of connection films COF1 and COF2. The drive IC may correspond to a component configured to process data for displaying the image and process a driving signal for processing the data. The drive IC may be disposed in ways such as a chip-on-glass (COG) method, a chip-on-film (COF) method, and a tape carrier package (TCP) method depending on how the drive IC is mounted. For convenience of description, the configuration has been described in which the drive ICs are mounted on the plurality of connection films COF1 and COF2 by the chip-on-film method. However, the present specification is not limited thereto. In addition, the drive IC may be integrated with the timing controller TD and disposed as a single chip.

The printed circuit board PCB may be electrically connected to the plurality of connection films COF1 and COF2. The printed circuit board PCB may supply signals to the drive ICs mounted on the plurality of connection films COF1 and COF2. Various types of components for supplying the drive IC with various signals such as driving signals, data signals, and the like may be disposed on the printed circuit board PCB.

Meanwhile, FIG. 8 illustrates that the display device 100 includes one printed circuit board PCB. However, this is provided for illustrative purposes only, and the embodiment of the present specification is not limited thereto. For example, the display device 100 may include two or more printed circuit boards PCB.

The display panel PN may include a display area AA, and a non-display area NA configured to surround the display area AA. The plurality of pixels PX may be disposed in the row direction and the column direction, e.g., the second direction Y and the first direction X in the display area AA of the display panel PN and display images. Various constituent elements for operating the pixel circuit disposed in the pixel PX may be disposed in the non-display area of the display panel PN.

The display area AA of the display panel PN may include a plurality of areas A1, A2, A3, and A4 extending in the column direction, e.g., the first direction X and separated in the row direction, e.g., the second direction Y. For example, the display area AA may include a first area A1, a second area A2 adjacent to the first area A1 in the second direction Y, a third area A3 adjacent to the second area A2 in the second direction Y, and a fourth area A4 adjacent to the third area A3 in the second direction Y.

Meanwhile, FIG. 8 illustrates that the display area AA is divided into four areas in the second direction Y. However, this is provided for illustrative purposes only, and the present specification is not limited thereto. The display area AA may be divided into various areas.

The plurality of areas A1, A2, A3, and A4 may each be an area in which the plurality of pixels PX in which the same selection signal line is disposed in the corresponding area and applies the same selection signal is disposed. For example, in the plurality of pixels PX disposed in the first area A1 among the plurality of areas A1, A2, A3, and A4, one first selection signal line and one second selection signal line may be connected in common.” Therefore, the same first selection signal Ss and the same second selection signal Ps are provided to the plurality of pixels PX disposed in the first area A1, such that the plurality of pixels PX disposed in the first area A1 may be controlled in the same drive mode. Likewise, the plurality of pixels PX disposed in the second area A2 may be controlled in the same drive mode, the plurality of pixels PX disposed in the third area A3 may be controlled in the same drive mode, and the plurality of pixels PX disposed in the fourth area A4 may be controlled in the same drive mode.

In addition, the plurality of areas A1, A2, A3, and A4 of the display area AA may be controlled independently. For example, different selection signal lines may be respectively disposed in the plurality of areas A1, A2, A3, and A4 of the display area AA, such that the plurality of areas A1, A2, A3, and A4 may be controlled independently. For example, in case that the display area AA is divided into four areas, e.g., the first area A1, the second area A2, the third area A3, and the fourth area A4, different first selection signal lines and different second selection signal lines may be respectively disposed in the first area A1, the second area A2, the third area A3, and the fourth area A4 may independently provide the first selection signal Ss and the second selection signal Ps to the plurality of pixels PX disposed in each of the areas. Therefore, the drive modes of the plurality of areas A1, A2, A3, and A4 of the display area AA may be controlled independently.

Meanwhile, the plurality of connection films COF1 and COF2 may each operate the plurality of areas adjacent to the plurality of divided areas A1, A2, A3, and A4 of the display area AA. For example, the plurality of connection films COF1 and COF2 may each operate two adjacent areas among the plurality of divided areas A1, A2, A3, and A4 of the display area AA. For example, as described above, in case that the plurality of connection films COF1 and COF2 includes the two connection films, i.e., the first connection film COF1 and the second connection film COF2 and the display area AA is divided into the four areas, i.e., the first area A1, the second area A2, the third area A3, and the fourth area A4, the first connection film COF1 may provide the power voltage, the data voltage Vdata, various types of signals, and the like to the plurality of pixels PX disposed in the first area A1 and the second area A2, and the second connection film COF2 may provide the power voltage, the data voltage Vdata, various types of signals, and the like to the plurality of pixels PX disposed in the third area A3 and the fourth area A4. However, the present specification is not limited thereto. The plurality of connection films COF1 and COF2 may respectively operate the plurality of divided areas A1, A2, A3, and A4 of the display area AA or operate three or more adjacent areas among the plurality of areas A1, A2, A3, and A4.

Hereinafter, for convenience of description, a configuration will be described in which the plurality of connection films COF1 and COF2 includes two connection films, i.e., the first connection film COF1 and the second connection film COF2, the display area AA is divided into four areas, i.e., the first area A1, the second area A2, the third area A3, and the fourth area A4, and the first connection film COF1 and the second connection film COF2 each operate two adjacent areas among the plurality of areas A1, A2, A3, and A4 of the display area AA.

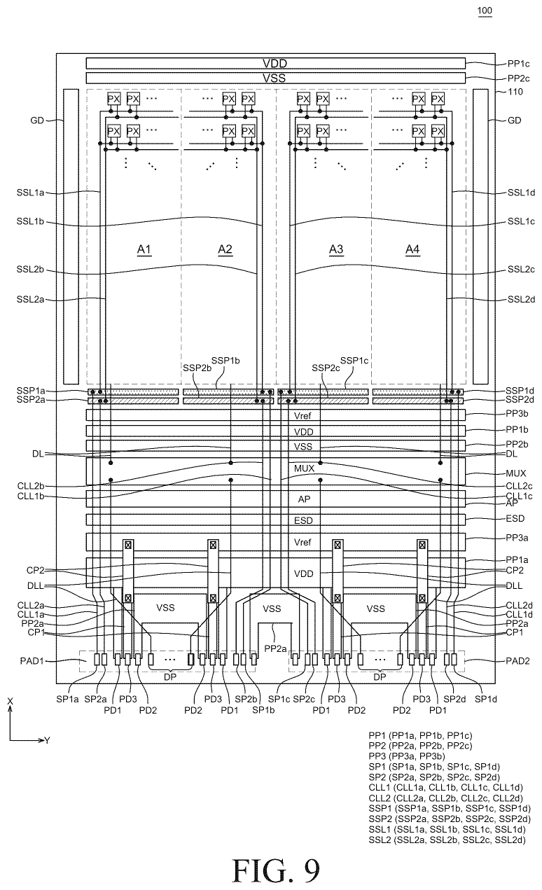

FIG. 9 is a top plan view of the display device according to an embodiment of the present specification.

Meanwhile, for convenience of description, in FIG. 9, based on a plane defined in the first direction X and the second direction Y, one side of the display device 100 based on the first direction X is defined as an upper side or an upward side, one side of the display device 100 based on a direction opposite to the first direction X is defined as a lower side or a downward side, one side of the display device 100 based on the second direction Y is defined as a right side, and one side of the display device 100 based on a direction opposite to the second direction Y is defined as a left side.

With reference to FIGS. 8 and 9, the display device 100 may include the substrate 110, the gate drive circuit GD, a plurality of pad parts PAD1 and PAD2, a plurality of power source patterns PP1, PP2, and PP3, a data distribution circuit MUX, an antistatic part ESD, an illumination inspection part AP, a first selection signal pattern SSP1, a second selection signal pattern SSP2, and various types of signal lines.

The substrate 110 may include the display area AA, and the non-display area NA disposed outside the display area AA. For example, the non-display area NA may be disposed to surround the display area AA.

Meanwhile, as described above, the display area AA may be divided into the plurality of areas, e.g., the first area A1, the second area A2, the third area A3, and the fourth area A4. The plurality of pixels PX may be disposed in the plurality of areas A1, A2, A3, and A4 included in the display area AA of the substrate 110. In this case, as described with reference to FIG. 8, the modes of the plurality of areas A1, A2, A3, and A4 of the display area AA may be controlled independently.

Various constituent elements may be disposed in the non-display area NA to operate the plurality of pixels PX included in the plurality of areas A1, A2, A3, and A4 of the display area AA. For example, the gate drive circuit GD, the plurality of pad parts PAD1 and PAD2, the plurality of power source patterns PP1, PP2, and PP3, the data distribution circuit MUX, the antistatic part ESD, the illumination inspection part AP, the first selection signal pattern SSP1, the second selection signal pattern SSP2, and various types of signal lines may be disposed in the non-display area NA of the substrate 110.

The gate drive circuit GD may supply gate signals to the plurality of pixels PX disposed in the plurality of areas A1, A2, A3, and A4 of the display area AA. For example, the gate drive circuit GD may supply a gate signal in the form of a shift register.

The gate drive circuit GD may be disposed in the non-display area NA of the substrate 110. For example, the gate drive circuit GD may be disposed in the non-display area NA of the substrate 110 in a gate-in-panel (GIP) manner.

In addition, in the non-display area NA of the substrate 110, two gate drive circuits GD may be disposed at two opposite sides of the display area AA. That is, the two gate drive circuits GD may supply, in a double feeding manner, the gate signals to the plurality of pixels PX disposed in the display area AA. However, this is provided for illustrative purposes only, and the present specification is not limited thereto. The display device 100 may include only one gate drive circuit GD disposed at one side of the display area AA.

The plurality of pad parts PAD1 and PAD2 may include a plurality of data pads DP disposed at a lowermost end of the non-display area NA of the substrate 110 and configured to provide the data voltage Vdata, a plurality of signal pads SP1 and SP2 configured to provide the selection signals, and a plurality of power pads PD1, PD2, and PD3 configured to provide power voltages to a plurality of power source patterns PP1, PP2, and PP3. Meanwhile, the pad part may be defined as a pad area in which various types of pads are disposed.

The plurality of pad parts PAD1 and PAD2 may be electrically connected to the plurality of connection films COF1 and COF2, which have been described with reference to FIG. 8, and receive various types of signals and various types of power voltages. For example, in case that the display device 100 includes the two connection films, e.g., the first connection film COF1 and the second connection film COF2 as described above, the plurality of pad parts PAD1 and PAD2 may include a first pad part PAD1 electrically connected to the first connection film COF1, and a second pad part PAD2 electrically connected to the second connection film COF2. Therefore, the selection signals, which are applied to the first and second areas A1 and A2 adjacent to each other among the plurality of areas of the display area AA may be provided to the plurality of signal pads SP1 and SP2 included in the first pad part PAD1, and the selection signals, which are applied to the third and fourth areas A3 and A4 adjacent to each other among the plurality of areas of the display area AA, may be provided to the plurality of signal pads SP1 and SP2 included in the second pad part PAD2.

The plurality of power source patterns PP1, PP2, and PP3 may be disposed in the non-display area NA, receive the power voltages from the plurality of power pads PD1, PD2, and PD3, and supply the power voltages to the plurality of pixels PX disposed in the display area AA. For example, the plurality of power source patterns PP1, PP2, and PP3 may include a first power source pattern PP1 configured to transmit the high-potential power voltage VDD to the plurality of pixels PX, a second power source pattern PP2 configured to transmit the low-potential power voltage VSS to the plurality of pixels PX, and a third power source pattern PP3 configured to transmit the reference voltage Vref to the plurality of pixels PX. Meanwhile, in the present specification, the term ‘power source pattern’ may change to a power line.

The first power source pattern PP1 may be disposed in the non-display area NA, i.e., the non-display area NA positioned above and/or below the display area AA. For example, the first power source pattern PP1 may include a first-first power source pattern PPla, a first-second power source pattern PP1b, and a first-third power source pattern PP1c.

The first-first power source pattern PPla may be disposed in the non-display area NA, i.e., the non-display area NA positioned below the display area AA. For example, the first-first power source pattern PPla may be disposed in the non-display area NA between the display area AA and the plurality of pad parts PAD1 and PAD2.

The first-first power source pattern PPla may include a first part extending in the second direction Y, and a plurality of second parts extending from the first part in a downward direction, e.g., a direction opposite to the first direction X. The first part and the plurality of second parts of the first-first power source pattern PPla may be integrated.

The plurality of second parts of the first-first power source pattern PPla may be respectively electrically connected to the plurality of first power pads PD1 included in the plurality of pad parts PAD1 and PAD2. Therefore, the first-first power source pattern PPla may receive the high-potential power voltage VDD from the first power pad PD1.

The first-second power source pattern PP1b may be disposed in the non-display area NA, i.e., the non-display area NA positioned below the display area AA. For example, the first-second power source pattern PP1b may be disposed in the non-display area NA between the display area AA and the first-first power source pattern PPla.

The first-second power source pattern PP1b may have a shape extending in the second direction Y. Meanwhile, although not illustrated in FIG. 9, the first-second power source pattern PP1b may be electrically connected to the first-first power source pattern PPla through a line extending at least in the first direction X. Therefore, the first-second power source pattern PP1b may receive the high-potential power voltage VDD.

The first-third power source pattern PP1c may be disposed in the non-display area NA, i.e., the non-display area NA positioned above the display area AA. The first-third power source pattern PPlc may have a shape extending in the second direction Y. Meanwhile, although not illustrated in FIG. 9, the first-third power source pattern PP1c may be electrically connected to the first-first power source pattern PPla and/or the first-second power source pattern PP1b through a line extending at least in the first direction X. Therefore, the first-third power source pattern PP1c may receive the high-potential power voltage VDD.

The first power source pattern PP1 may transmit the high-potential power voltage VDD to the plurality of pixels PX disposed in the display area AA. For example, the high-potential power voltage VDD may be provided to the plurality of pixels PX, which is disposed in the display area AA, through the high-potential power line electrically connected to the first power source pattern PP1. For example, the first-second power source pattern PP1b disposed below the display area AA may provide the high-potential power voltage VDD to the plurality of pixels PX disposed in a lower area of the display area AA through the high-potential power line, and the first-third power source pattern PP1c disposed above the display area AA may provide the high-potential power voltage VDD to the plurality of pixels PX disposed in an upper area of the display area AA through the high-potential power line. However, the present specification is not limited thereto.

The second power source pattern PP2 may be disposed in the non-display area NA, i.e., the non-display area NA positioned above and/or below the display area AA. For example, the second power source pattern PP2 may include a second-first power source pattern PP2a, a second-second power source pattern PP2b, and a second-third power source pattern PP2c.

The second-first power source pattern PP2a may be disposed in the non-display area NA, i.e., the non-display area NA positioned below the display area AA. For example, the second-first power source pattern PP2a may be disposed in the non-display area NA between the display area AA and the plurality of pad parts PAD1 and PAD2. For example, the second-first power source pattern PP2a may be disposed between the first-first power source pattern PPla of the first power source pattern PP1 and the plurality of pad parts PAD1 and PAD2.

According to the embodiment, the second power source pattern PP2 may include a plurality of second-first power source patterns PP2a. For example, the plurality of second-first power source patterns PP2a may include the second-first power source pattern PP2a electrically connected to at least one second power pad PD2 included in the first pad part PAD1, the second-first power source pattern PP2a electrically connected to at least one second power pad PD2 included in the first pad part PAD1 and at least one second power pad PD2 included in the second pad part PAD2, and the second-first power source pattern PP2a electrically connected to at least one second power pad PD2 included in the second pad part PAD2. However, the present specification is not limited thereto.

The plurality of second-first power source patterns PP2a may each include a third part extending in the second direction Y, and a plurality of fourth parts extending from the third part in the downward direction, e.g., the direction opposite to the first direction X. The third part and the plurality of fourth parts of each of the plurality of second-first power source patterns PP2a may be integrated.

The plurality of fourth parts of each of the plurality of second-first power source patterns PP2a may be respectively electrically connected to the plurality of second power pads PD2 included in the plurality of pad parts PAD1 and PAD2. Therefore, the plurality of second-first power source patterns PP2a may each receive the low-potential power voltage VSS from the second power pad PD2.

The second-second power source pattern PP2b may be disposed in the non-display area NA, i.e., the non-display area NA positioned below the display area AA. For example, the second-second power source pattern PP2b may be disposed in the non-display area NA between the display area AA and the second-first power source pattern PP2a. For example, the second-second power source pattern PP2b may be disposed between the first-first power source pattern PPla of the first power source pattern PP1 and the first-second power source pattern PP1b.

The second-second power source pattern PP2b may have a shape extending in the second direction Y. Meanwhile, although not illustrated in FIG. 9, the second-second power source pattern PP2b may be electrically connected to at least one of the plurality of second-first power source patterns PP2a through a line extending at least in the first direction X. Therefore, the second-second power source pattern PP2b may receive the low-potential power voltage VSS.

The second-third power source pattern PP2c may be disposed in the non-display area NA, i.e., the non-display area NA positioned above the display area AA. The second-third power source pattern PP2c may have a shape extending in the second direction Y. Meanwhile, although not illustrated in FIG. 9, the second-third power source pattern PP2c may be electrically connected to at least one of the plurality of second-first power source patterns PP2a and/or the second-second power source pattern PP2b through a line extending at least in the first direction X. Therefore, the second-third power source pattern PP2c may receive the low-potential power voltage VSS. The second power source pattern PP2 may transmit the low-potential power voltage VSS to the plurality of pixels PX disposed in the display area AA. For example, the low-potential power voltage VSS may be provided to the plurality of pixels PX, which is disposed in the display area AA, through the low-potential power line electrically connected to the second power source pattern PP2. For example, the second-second power source pattern PP2b disposed below the display area AA may provide the low-potential power voltage VSS to the plurality of pixels PX disposed in the lower area of the display area AA through the low-potential power line, and the second-third power source pattern PP2c disposed above the display area AA may provide the low-potential power voltage VSS to the plurality of pixels PX disposed in the upper area of the display area AA through the low-potential power line. However, the present specification is not limited thereto.

The third power source pattern PP3 may be disposed in the non-display area NA, i.e., the non-display area NA positioned below the display area AA. For example, the third power source pattern PP3 may include a third-first power source pattern PP3a and a third-second power source pattern PP3b.

The third-first power source pattern PP3a may be disposed in the non-display area NA, i.e., the non-display area NA positioned below the display area AA. For example, the third-first power source pattern PP3a may be disposed in the non-display area NA between the display area AA and the plurality of pad parts PAD1 and PAD2. For example, the third-first power source pattern PP3a may be disposed between the display area AA and the first-first power source pattern PPla of the first power source pattern PP1.

The third-first power source pattern PP3a may have a shape extending in the second direction Y. The third-first power source pattern PP3a may be electrically connected to the plurality of third power pads PD3 included in the plurality of pad parts PAD1 and PAD2 through a plurality of power source connection patterns CP1 and CP2. For example, the plurality of first power source connection patterns CP1 may each be electrically connected to the third power pad PD3 included in each of the plurality of pad parts PAD1 and PAD2, one end of each of the plurality of second power source connection patterns CP2 may be connected to each of the plurality of first power source connection patterns CP1, and the other end of each of the plurality of second power source connection patterns CP2 may be connected to the third-first power source pattern PP3a. Therefore, the third-first power source pattern PP3a may receive the reference voltage Vref from the third power pad PD3 through the plurality of power source connection patterns CP1 and CP2.

The third-second power source pattern PP3b may be disposed in the non-display area NA, i.e., the non-display area NA positioned below the display area AA. For example, the third-second power source pattern PP3b may be disposed in the non-display area NA between the display area AA and the third-first power source pattern PP3a. For example, the third-second power source pattern PP3b may be disposed between the display area AA and the first-second power source pattern PP1b of the first power source pattern PP1.

The third-second power source pattern PP3b may have a shape extending in the second direction Y. Meanwhile, although not illustrated in FIG. 9, the third-second power source pattern PP3b may be electrically connected to the third-first power source pattern PP3a through a line extending at least in the first direction X. Therefore, the third-second power source pattern PP3b may receive the reference voltage Vref.

The third power source pattern PP3 may transmit the reference voltage Vref to the plurality of pixels PX disposed in the display area AA. For example, the reference voltage Vref may be provided to the plurality of pixels PX disposed in the display area AA through the reference voltage line electrically connected to the third power source pattern PP3. For example, the third-second power source pattern PP3b may provide the reference voltage Vref to the plurality of pixels PX disposed in the display area AA through the reference voltage line. However, the present specification is not limited thereto.

According to the embodiment, the plurality of power source patterns PP1, PP2, and PP3 may include a metallic material excellent in conductivity to provide the power voltage. However, the present specification is not limited thereto.

However, the shapes and arrangements of and the connection relationships between the plurality of power source patterns PP1, PP2, and PP3 described above are provided for illustrative purposes only and may be variously modified in accordance with design of the display device 100.

Meanwhile, as described with reference to FIG. 8, the data drive circuits DD, e.g., the drive ICs such as the data driver ICs may be disposed on the plurality of connection films COF1 and COF2. The data drive circuit DD disposed on the plurality of connection films COF1 and COF2 may provide the data voltage Vdata through the plurality of data pads DP included in the plurality of pad parts PAD1 and PAD2.

In addition, a plurality of data connection lines DLL extending in the first direction X may be respectively electrically connected to the plurality of data pads DP. Therefore, the plurality of data connection lines DLL may each receive the data voltage Vdata.

The plurality of data connection lines DLL may each be connected to the data distribution circuit MUX and electrically connected to one data line DL selected from the plurality of data lines DL disposed in the display area AA by an operation of the data distribution circuit MUX, such that the plurality of data connection lines DLL may each transmit the data voltage Vdata to the corresponding data line DL. Therefore, the data voltage Vdata may be provided to the plurality of pixels PX disposed in the display area AA.

The data distribution circuit MUX may distribute the data voltage Vdata, which is transmitted by the plurality of data connection lines DLL, into the plurality of data lines DL in a time division manner. For example, the data distribution circuit MUX may electrically connect one data connection line DLL of the plurality of data connection lines DLL to each of the plurality of data lines DL disposed in the display area AA. For example, the data distribution circuit MUX may be implemented as a multiplexer. However, the present specification is not limited thereto.

The data distribution circuit MUX may be disposed in the non-display area NA, i.e., the non-display area NA positioned below the display area AA.

The illumination inspection part AP may check whether the plurality of pixels PX disposed in the display area AA operates abnormally before the shipment of the display device 100. For example, the illumination inspection part AP may include a plurality of illumination inspection switches used to inspect an auto-probe (A/P) by performing an illumination inspection for checking whether the pixel PX operates by applying data illumination inspection signals and mode illumination inspection signals to the plurality of pixels PX before the shipment of the display device 100.

The illumination inspection part AP may be disposed in the non-display area NA, i.e., the non-display area NA positioned below the display area AA. For example, the illumination inspection part AP, e.g., the plurality of illumination inspection switches included in the illumination inspection part AP may be disposed in the non-display area NA remaining after a trimming process of removing an illumination inspection pad part configured to provide the data illumination inspection signal and/or the mode illumination inspection signal to the plurality of illumination inspection switches after the illumination inspection is performed on the display device 100. However, this is provided for illustrative purposes only. The illumination inspection pad part configured to provide the data illumination inspection signal and/or the mode illumination inspection signal to the plurality of illumination inspection switches may remain in the non-display area NA of the display device 100 without being removed.

The antistatic part ESD may discharge static electricity applied to the plurality of data lines DL and/or a plurality of selection signal lines SSL1 and SSL2, thereby protecting the plurality of data lines DL and/or the plurality of selection signal lines SSL1 and SSL2 from the static electricity.

The antistatic part ESD may be disposed in the non-display area NA, i.e., the non-display area NA positioned below the display area AA.

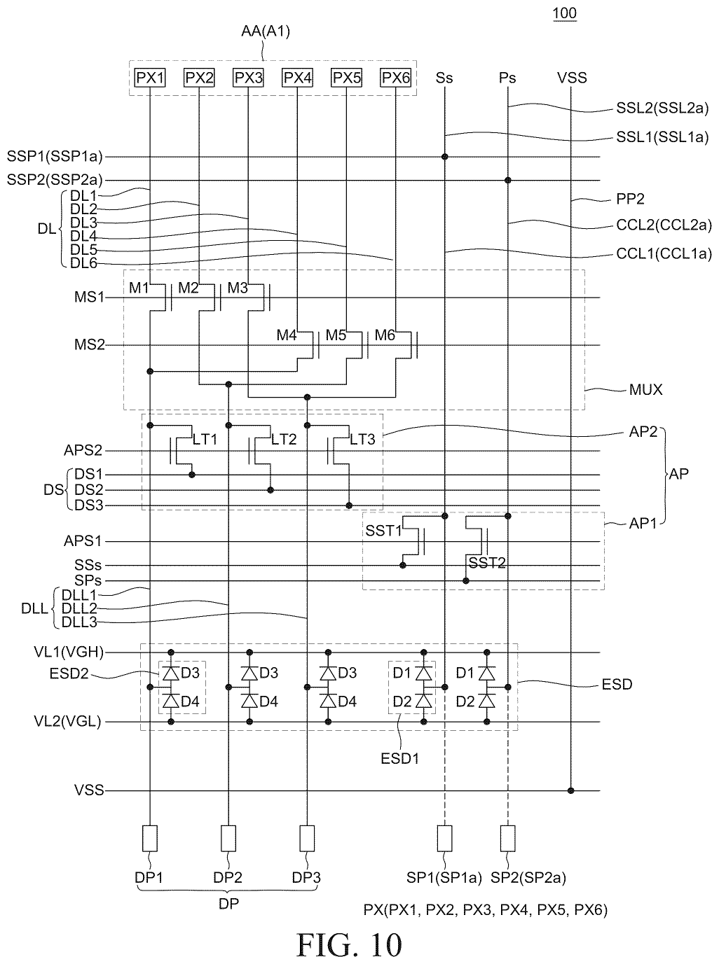

The data distribution circuit MUX, the illumination inspection part AP, and the antistatic part ESD will be described below in detail with reference to FIG. 10.

A plurality of first signal pads SP1 and a plurality of second signal pads SP2 may be respectively disposed on the plurality of pad parts PAD1 and PAD2 and supply the first selection signal Ss and the second selection signal Ps provided to the plurality of pixels PX disposed in the corresponding area among the plurality of areas A1, A2, A3, and A4 of the display area AA. For example, the plurality of first signal pads SP1 may include a first-first signal pad SPla and a first-second signal pad SP1b disposed on the first pad part PAD1, and a first-third signal pad SP1c and a first-fourth signal pad SP1d disposed on the second pad part PAD2. In addition, the plurality of second signal pads SP2 may include a second-first signal pad SP2a and a second-second signal pad SP2b disposed on the first pad part PAD1, and a second-third signal pad SP2c and a second-fourth signal pad SP2d disposed on the second pad part PAD2.

For example, the first pad part PAD1 may include the first-first signal pad SPla to which the first selection signal Ss provided to the plurality of pixels PX disposed in the first area A1 is supplied, the first-second signal pad SP1b to which the first selection signal Ss provided to the plurality of pixels PX disposed in the second area A2 is supplied, the second-first signal pad SP2a to which the second selection signal Ps provided to the plurality of pixels PX disposed in the first area A1 is supplied, and the second-second signal pad SP2b to which the second selection signal Ps provided to the plurality of pixels PX disposed in the second area A2 is supplied.

In addition, the second pad part PAD2 may include the first-third signal pad SP1c to which the first selection signal Ss provided to the plurality of pixels PX disposed in the third area A3 is supplied, the first-fourth signal pad SP1d to which the first selection signal Ss provided to the plurality of pixels PX disposed in the fourth area A4 is supplied, the second-third signal pad SP2c to which the second selection signal Ps provided to the plurality of pixels PX disposed in the third area A3 is supplied, and the second-fourth signal pad SP2d to which the second selection signal Ps provided to the plurality of pixels PX disposed in the fourth area A4 is supplied.

A plurality of first connection lines CLL1 and a plurality of second connection lines CLL2 may be disposed in the non-display area NA and extend in the first direction X.

One end of each of the plurality of first connection lines CLL1 may be electrically connected to the corresponding first signal pad among the plurality of first signal pads SP1 disposed on the plurality of pad parts PAD1 and PAD2. Therefore, plurality of first connection lines line CLL1 may receive the first selection signal Ss provided to the corresponding area of the display area AA.

For example, the plurality of first connection lines CLL1 may include a first-first connection line CLL1a disposed on the first pad part PAD1 and electrically connected to the first-first signal pad SP1a to which the first selection signal Ss provided to the plurality of pixels PX disposed in the first area A1 is supplied, a first-second connection line CLL1b disposed on the first pad part PAD1 and electrically connected to the first-second signal pad SP1b to which the first selection signal Ss provided to the plurality of pixels PX disposed in the second area A2 is supplied, a first-third connection line CLL1c provided on the second pad part PAD2 and electrically connected to the first-third signal pad SP1c to which the first selection signal Ss provided to the plurality of pixels PX disposed in the third area A3 is supplied, and a first-fourth connection line CLL1d disposed on the second pad part PAD2 and electrically connected to the first-fourth signal pad SP1d to which the first selection signal Ss provided to the plurality of pixels PX disposed in the fourth area A4 is supplied. Therefore, the first-first connection line CLL1a may receive the first selection signal Ss provided to the first area A1, the first-second connection line CLL1b may receive the first selection signal Ss provided to the second area A2, the first-third connection line CLL1c may receive the first selection signal Ss provided to the third area A3, and the first-fourth connection line CLL1d may receive the first selection signal Ss provided to the fourth area A4.

One end of each of the plurality of second connection lines CLL2 may be electrically connected to the corresponding second signal pad among the plurality of second signal pads SP2 disposed on the plurality of pad parts PAD1 and PAD2. Therefore, the plurality of second connection lines CLL2 may receive the second selection signal Ps provided to the corresponding area of the display area AA.

For example, the plurality of second connection lines CLL2 may include a second-first connection line CLL2a disposed on the first pad part PAD1 and electrically connected to the second-first signal pad SP2a to which the second selection signal Ps provided to the plurality of pixels PX disposed in the first area A1 is supplied, a second-second connection line CLL2b disposed on the first pad part PAD1 and electrically connected to the second-second signal pad SP2b to which the second selection signal Ps provided to the plurality of pixels PX disposed in the second area A2 is supplied, a second-third connection line CLL2c disposed on the second pad part PAD2 and electrically connected to the second-third signal pad SP2c to which the second selection signal Ps provided to the plurality of pixels PX disposed in the third area A3 is supplied, and a second-fourth connection line CLL2d disposed on the second pad part PAD2 and electrically connected to the second-fourth signal pad SP2d to which the second selection signal Ps provided to the plurality of pixels PX disposed in the fourth area A4 is supplied. Therefore, the second-first connection line CLL2a may receive the second selection signal Ps provided to the first area A1, the second-second connection line CLL2b may receive the second selection signal Ps provided to the second area A2, the second-third connection line CLL2c may receive the second selection signal Ps provided to the third area A3, and the second-fourth connection line CLL2d may receive the second selection signal Ps provided to the fourth area A4.

The plurality of first selection signal patterns SSP1 and the plurality of second selection signal patterns SSP2 may each be disposed in the non-display area NA and extend in the second direction Y. For example, the plurality of first selection signal patterns SSP1 and the plurality of second selection signal patterns SSP2 may each be disposed in the non-display area NA below the display area AA.

A planar shape of each of the plurality of first selection signal patterns SSP1 and a planar shape of each of the plurality of second selection signal patterns SSP2 may each have a bar shape extending in one direction, e.g., the second direction Y. For example, the plurality of first selection signal patterns SSP1 and the plurality of second selection signal patterns SSP2 may each have a shape extending in the second direction Y and having a predetermined width in the first direction X. For example, a width in the first direction X of each of the plurality of first selection signal patterns SSP1 and the plurality of second selection signal patterns SSP2 may be larger than a width of each of the other signal lines, e.g., the plurality of selection signal lines SSL1 and SSL2 and/or the plurality of connection lines CLL1 and CLL2. However, the present specification is not limited thereto.

The plurality of first selection signal patterns SSP1 may each be disposed in the non-display area NA positioned below the corresponding area of the display area AA, and the plurality of first selection signal patterns SSP1 may each be electrically connected to the other end of the corresponding first connection line CLL1 among the plurality of first connection lines CLL1. Therefore, the first selection signal Ss, which is provided to the corresponding area of the display area AA, may be supplied to each of the plurality of first selection signal patterns SSP1 through the first connection line CLL1 electrically connected to the corresponding first selection signal pattern SSP1.

For example, the plurality of first selection signal patterns SSP1 may include a first-first selection signal pattern SSP1a disposed in the non-display area NA below the first area A1, a first-second selection signal pattern SSP1b disposed in the non-display area NA below the second area A2, a first-third selection signal pattern SSP1c disposed in the non-display area NA below the third area A3, and a first-fourth selection signal pattern SSP1d disposed in the non-display area NA below the fourth area A4.

The first-first selection signal pattern SSP1a may be electrically connected to the other end of the first-first connection line CLL1a, the first-second selection signal pattern SSP1b may be electrically connected to the other end of the first-second connection line CLL1b, the first-third selection signal pattern SSP1c may be electrically connected to the other end of the first-third connection line CLL1c, and the first-fourth selection signal pattern SSP1d may be electrically connected to the other end of the first-fourth connection line CLL1d. Therefore, the first selection signal Ss provided to the first area A1 may be supplied to the first-first selection signal pattern SSP1a, the first selection signal Ss provided to the second area A2 may be supplied to the first-second selection signal pattern SSP1b, the first selection signal Ss provided to the third area A3 may be supplied to the first-third selection signal pattern SSP1c, and the first selection signal Ss provided to the fourth area A4 may be supplied to the first-fourth selection signal pattern SSP1d.

In addition, the plurality of second selection signal patterns SSP2 may each be disposed in the non-display area NA positioned below the corresponding area of the display area AA, and the plurality of second selection signal patterns SSP2 may be electrically connected to the other end of the corresponding second connection line CLL2 of the plurality of second connection lines CLL2. Therefore, the second selection signal Ps, which is provided to the corresponding area of the display area AA, may be supplied to the plurality of second selection signal patterns SSP2 through the second connection line CLL2 electrically connected to the corresponding second selection signal pattern SSP2.

For example, the plurality of second selection signal patterns SSP2 may include a second-first selection signal pattern SSP2a disposed in the non-display area NA below the first area A1, a second-second selection signal pattern SSP2b disposed in the non-display area NA below the second area A2, a second-third selection signal pattern SSP2c disposed in the non-display area NA below the third area A3, and a second-fourth selection signal pattern SSP2d disposed in the non-display area NA below the fourth area A4.

The second-first selection signal pattern SSP2a may be electrically connected to the other end of the second-first connection line CLL2a, the second-second selection signal pattern SSP2b may be electrically connected to the other end of the second-second connection line CLL2b, the second-third selection signal pattern SSP2c may be electrically connected to the other end of the second-third connection line CLL2c, and the second-fourth selection signal pattern SSP2d may be electrically connected to the other end of the second-fourth connection line CLL2d. Therefore, the second selection signal Ps provided to the first area A1 may be supplied to the second-first selection signal pattern SSP2a, the second selection signal Ps provided to the second area A2 may be supplied to the second-second selection signal pattern SSP2b, the second selection signal Ps provided to the third area A3 may be supplied to the second-third selection signal pattern SSP2c, and the second selection signal Ps provided to the fourth area A4 may be supplied to the second-fourth selection signal pattern SSP2d.

According to the embodiment, the plurality of first selection signal patterns SSP1 and the plurality of second selection signal patterns SSP2 may each include a metallic material excellent in conductivity to provide the selection signal. However, the present specification is not limited thereto.

The plurality of first selection signal lines SSL1 and the plurality of second selection signal lines SSL2 may each be disposed to extend from the non-display area NA to the display area AA.

One end of each of the plurality of first selection signal lines SSL1 may be electrically connected to the corresponding first selection signal pattern among the plurality of first selection signal patterns SSP1. Therefore, the plurality of first selection signal lines SSL1 may receive the first selection signal Ss provided to the corresponding area of the display area AA.

For example, the plurality of first selection signal lines SSL1 may include a first-first selection signal line SSL1a disposed below the first area A1 and electrically connected to the first-first selection signal pattern SSP1a to which the first selection signal Ss provided to the plurality of pixels PX disposed in the first area A1 is supplied, a first-second selection signal line SSL1b disposed below the second area A2 and electrically connected to the first-second selection signal pattern SSP1b to which the first selection signal Ss provided to the plurality of pixels PX disposed in the second area A2 is supplied, a first-third selection signal line SSL1c disposed below the third area A3 and electrically connected to the first-third selection signal pattern SSP1c to which the first selection signal Ss provided to the plurality of pixels PX disposed in the third area A3 is supplied, and a first-fourth selection signal line SSL1d disposed below the fourth area A4 and electrically connected to the first-fourth selection signal pattern SSP1d to which the first selection signal Ss provided to the plurality of pixels PX disposed in the fourth area A4 is supplied.

Therefore, the first-first selection signal line SSL1a may receive the first selection signal Ss provided to the first area A1, the first-second selection signal line SSL1b may receive the first selection signal Ss provided to the second area A2, the first-third selection signal line SSL1c may receive the first selection signal Ss provided to the third area A3, and the first-fourth selection signal line SSL1d may receive the first selection signal Ss provided to the fourth area A4.

In addition, the plurality of first selection signal lines SSL1 may each be connected to the plurality of pixels PX disposed in the corresponding area and provide the first selection signal Ss.

To this end, the plurality of first selection signal lines SSL1 may each include a main line extending in the first direction X, and a plurality of auxiliary lines branching off from the main line and disposed to extend in the second direction Y or a direction opposite to the second direction Y.

For example, the first-first selection signal line SSL1a may include a first main line having one end electrically connected to the first-first selection signal pattern SSP1a and disposed to extend in the first direction X from the non-display area NA to the display area AA, and a plurality of first auxiliary lines branching off from the first main line and disposed to extend in the second direction Y. In this case, the plurality of first auxiliary lines of the first-first selection signal line SSL1a may be formed in pixel rows. For example, the number of first auxiliary lines of the first-first selection signal line SSL1a may be equal to the number of pixel rows of the display area AA. The plurality of first auxiliary lines may each be connected in common to the plurality of pixels PX disposed in the corresponding pixel rows of the plurality of pixels PX disposed in the first area A1, and the plurality of first auxiliary lines may provide the first selection signal Ss. Therefore, the same first selection signal Ss may be provided to the plurality of pixels PX disposed in the first area A1.

In addition, the first-second selection signal line SSL1b may include a second main line having one end electrically connected to the first-second selection signal pattern SSP1b and disposed to extend in the first direction X from the non-display area NA to the display area AA, and a plurality of second auxiliary lines branching off from the second main line and disposed to extend in the direction opposite to the second direction Y. In this case, the plurality of second auxiliary lines of the first-second selection signal line SSL1b may be formed in pixel rows. For example, the number of second auxiliary lines of the first-second selection signal line SSL1b may be equal to the number of pixel rows of the display area AA. The plurality of second auxiliary lines may each be connected in common to the plurality of pixels PX disposed in the corresponding pixel rows of the plurality of pixels PX disposed in the second area A2, and the plurality of second auxiliary lines may provide the first selection signal Ss. Therefore, the same first selection signal Ss may be provided to the plurality of pixels PX disposed in the second area A2.

In addition, the first-third selection signal line SSL1c may include a third main line having one end electrically connected to the first-third selection signal pattern SSP1c and disposed to extend in the first direction X from the non-display area NA to the display area AA, and a plurality of third auxiliary lines branching off from the third main line and disposed to extend in the second direction Y. In this case, the plurality of third auxiliary lines of the first-third selection signal line SSL1c may be formed in pixel rows. For example, the number of third auxiliary lines of the first-third selection signal line SSL1c may be equal to the number of pixel rows of the display area AA. The plurality of third auxiliary lines may each be connected in common to the plurality of pixels PX disposed in the corresponding pixel rows of the plurality of pixels PX disposed in the third area A3, and the plurality of third auxiliary lines may provide the first selection signal Ss. Therefore, the same first selection signal Ss may be provided to the plurality of pixels PX disposed in the third area A3.

In addition, the first-fourth selection signal line SSL1d may include a fourth main line having one end electrically connected to the first-fourth selection signal pattern SSP1d and disposed to extend in the first direction X from the non-display area NA to the display area AA, and a plurality of fourth auxiliary lines branching off from the fourth main line and disposed to extend in the direction opposite to the second direction Y. In this case, the plurality of fourth auxiliary lines of the first-fourth selection signal line SSL1d may be formed in pixel rows. For example, the number of fourth auxiliary lines of the first-fourth selection signal line SSL1d may be equal to the number of pixel rows of the display area AA. The plurality of fourth auxiliary lines may each be connected in common to the plurality of pixels PX disposed in the corresponding pixel rows of the plurality of pixels PX disposed in the fourth area A4, and the plurality of fourth auxiliary lines may provide the first selection signal Ss. Therefore, the same first selection signal Ss may be provided to the plurality of pixels PX disposed in the fourth area A4.

One end of each of the plurality of second selection signal lines SSL2 may be electrically connected to the corresponding second selection signal pattern among the plurality of second selection signal patterns SSP2. Therefore, the plurality of second selection signal lines SSL2 may receive the second selection signal Ps provided to the corresponding area of the display area AA.

For example, the plurality of second selection signal lines SSL2 may include a second-first selection signal line SSL2a disposed below the first area A1 and electrically connected to the second-first selection signal pattern SSP2a to which the second selection signal Ps provided to the plurality of pixels PX disposed in the first area A1 is supplied, a second-second selection signal line SSL2b disposed below the second area A2 and electrically connected to the second-second selection signal pattern SSP2b to which the second selection signal Ps provided to the plurality of pixels PX disposed in the second area A2 is supplied, a second-third selection signal line SSL2c disposed below the third area A3 and electrically connected to the second-third selection signal pattern SSP2c to which the second selection signal Ps provided to the plurality of pixels PX disposed in the third area A3 is supplied, and a second-fourth selection signal line SSL2d disposed below the fourth area A4 and electrically connected to the second-fourth selection signal pattern SSP2d to which the second selection signal Ps provided to the plurality of pixels PX disposed in the fourth area A4 is supplied.

Therefore, the second-first selection signal line SSL2a may receive the second selection signal Ps provided to the first area A1, the second-second selection signal line SSL2b may receive the second selection signal Ps provided to the second area A2, the second-third selection signal line SSL2c may receive the second selection signal Ps provided to the third area A3, and the second-fourth selection signal line SSL2d may receive the second selection signal Ps provided to the fourth area A4.

In addition, the plurality of second selection signal lines SSL2 may each be connected to the plurality of pixels PX disposed in the corresponding area and provide the second selection signal Ps.

To this end, the plurality of second selection signal lines SSL2 may each include a main line extending in the first direction X, and a plurality of auxiliary lines branching off from the main line and disposed to extend in the second direction Y or the direction opposite to the second direction Y.

For example, the second-first selection signal line SSL2a may include a fifth main line having one end electrically connected to the second-first selection signal pattern SSP2a and disposed to extend in the first direction X from the non-display area NA to the display area AA, and a plurality of fifth auxiliary lines branching off from the fifth main line and disposed to extend in the second direction Y. In this case, the plurality of fifth auxiliary lines of the second-first selection signal line SSL2a may be formed in pixel rows. For example, the number of fifth auxiliary lines of the second-first selection signal line SSL2a may be equal to the number of pixel rows of the display area AA. The plurality of fifth auxiliary lines may each be connected in common to the plurality of pixels PX disposed in the corresponding pixel rows of the plurality of pixels PX disposed in the first area A1, and the plurality of fifth auxiliary lines may provide the second selection signal Ps. Therefore, the same second selection signal Ps may be provided to the plurality of pixels PX disposed in the first area A1.

In addition, the second-second selection signal line SSL2b may include a sixth main line having one end electrically connected to the second-second selection signal pattern SSP2b and disposed to extend in the first direction X from the non-display area NA to the display area AA, and a plurality of sixth auxiliary lines branching off from the sixth main line and disposed to extend in the direction opposite to the second direction Y. In this case, the plurality of sixth auxiliary lines of the second-second selection signal line SSL2b may be formed in pixel rows. For example, the number of sixth auxiliary lines of the second-second selection signal line SSL2b may be equal to the number of pixel rows of the display area AA. The plurality of sixth auxiliary lines may each be connected in common to the plurality of pixels PX disposed in the corresponding pixel rows of the plurality of pixels PX disposed in the second area A2, and the plurality of sixth auxiliary lines may provide the second selection signal Ps. Therefore, the same second selection signal Ps may be provided to the plurality of pixels PX disposed in the second area A2.

In addition, the second-third selection signal line SSL2c may include a seventh main line having one end electrically connected to the second-third selection signal pattern SSP2c and disposed to extend in the first direction X from the non-display area NA to the display area AA, and a plurality of seventh auxiliary lines branching off from the seventh main line and disposed to extend in the second direction Y. In this case, the plurality of seventh auxiliary lines of the second-third selection signal line SSL2c may be formed in pixel rows. For example, the number of seventh auxiliary lines of the second-third selection signal line SSL2c may be equal to the number of pixel rows of the display area AA. The plurality of seventh auxiliary lines may each be connected in common to the plurality of pixels PX disposed in the corresponding pixel rows of the plurality of pixels PX disposed in the third area A3, and the plurality of seventh auxiliary lines may provide the second selection signal Ps. Therefore, the same second selection signal Ps may be provided to the plurality of pixels PX disposed in the third area A3.

In addition, the second-fourth selection signal line SSL2d may include an eighth main line having one end electrically connected to the second-fourth selection signal pattern SSP2d and disposed to extend in the first direction X from the non-display area NA to the display area AA, and a plurality of eighth auxiliary lines branching off from the eighth main line and disposed to extend in the direction opposite to the second direction Y. In this case, the plurality of eighth auxiliary lines of the second-fourth selection signal line SSL2d may be formed in pixel rows. For example, the number of eighth auxiliary lines of the second-fourth selection signal line SSL2d may be equal to the number of pixel rows of the display area AA. The plurality of eighth auxiliary lines may each be connected in common to the plurality of pixels PX disposed in the corresponding pixel rows of the plurality of pixels PX disposed in the fourth area A4, and the plurality of eighth auxiliary lines may provide the second selection signal Ps. Therefore, the same second selection signal Ps may be provided to the plurality of pixels PX disposed in the fourth area A4.

As described above, the first selection signal Ss and the second selection signal Ps may be independently provided to the plurality of areas A1, A2, A3, and A4 of the display area AA, such that the drive modes of the plurality of areas A1, A2, A3, and A4 may be controlled independently.

In addition, the display device 100 according to the embodiment of the present specification may include the plurality of selection signal patterns SSP1 and SSP2 for providing the first selection signal Ss and the second selection signal Ps, thereby minimizing an RC delay of the selection signal.

For example, an RC delay may occur on the corresponding selection signal line in case that the selection signal is provided to the plurality of pixels PX disposed in all the corresponding areas among the plurality of areas A1, A2, A3, and A4 through the single selection signal line connected to the plurality of signal pads SP1 and SP2 to which the selection signal is provided in order to provide the first selection signal Ss and the second selection signal Ps to the plurality of pixels PX. In particular, because a width of the selection signal line for providing the selection signal to ensure a layout of the display device 100 is designed to be very small, resistance of the single selection signal line may increase, and the RC delay may occur severely.

Therefore, in the case of the display device 100 according to the embodiment of the present specification, the selection signal may be provided to the plurality of selection signal lines SSL1 and SSL2 through the plurality of selection signal patterns SSP1 and SSP2 electrically connected to the plurality of connection lines CLL1 and CLL2 connected to the plurality of signal pads SP1 and SP2 and configured to provide the selection signal, such that the resistance of the plurality of selection signal lines SSL1 and SSL2 may be reduced, and the RC delay, which may occur on the plurality of selection signal lines SSL1 and SSL2, may be minimized.

In addition, as described above, the plurality of selection signal patterns SSP1 and SSP2 may each be formed to have a width larger than a width of each of the other signal lines, e.g., the plurality of selection signal lines SSL1 and SSL2 and/or the plurality of connection lines CLL1 and CLL2, such that the resistance of each of the plurality of selection signal patterns SSP1 and SSP2 may be designed to be minimized, which may more effectively improve the RC delay that may occur on the plurality of selection signal lines SSL1 and SSL2.

FIG. 10 is an equivalent circuit diagram of the display device according to an embodiment of the present specification.

Meanwhile, FIG. 10 exemplarily illustrates an equivalent circuit diagram of the display device 100 corresponding to the plurality of pixels PX disposed in the first area A1, e.g., the first area A1 among the plurality of areas A1, A2, A3, and A4 included in the display area AA.

In addition, for convenience of description, FIG. 10 illustrates six pixels, e.g., a first pixel PX1, a second pixel PX2, a third pixel PX3, a fourth pixel PX4, a fifth pixel PX5, and a sixth pixel PX6 disposed in one row among the plurality of pixels PX disposed in the first area A1.

Therefore, hereinafter, based on the six pixels disposed in the first area A1 of the display area AA, the equivalent circuit of the display device 100 will be described. The equivalent circuit of the display device 100 may include a substantially identical or similar structure to not only the remaining pixels disposed in the first area A1 but also the pixels disposed in the second area A2, the third area A3, and the fourth area A4 of the display area AA.

Meanwhile, for convenience of description, the contents in FIG. 10, which are identical to the contents described with reference to FIGS. 8 and 9, will not be described repeatedly.

With reference to FIGS. 8 to 10, the display device 100 may include the first pixel PX1, the second pixel PX2, the third pixel PX3, the fourth pixel PX4, the fifth pixel PX5, and the sixth pixel PX6 disposed in the display area AA, e.g., the first area A1. In addition, the display device 100 may include the data distribution circuit MUX, the antistatic part ESD, and the illumination inspection part AP disposed in the non-display area NA.

The first pixel PX1, the second pixel PX2, the third pixel PX3, the fourth pixel PX4, the fifth pixel PX5, and the sixth pixel PX6 may each be connected to a corresponding data line among the plurality of data lines DL and receive the data voltage Vdata. For example, the first pixel PX1 may be connected to a first data line DL1, the second pixel PX2 may be connected to a second data line DL2, the third pixel PX3 may be connected to a third data line DL3, the fourth pixel PX4 may be connected to a fourth data line DL4, the fifth pixel PX5 may be connected to a fifth data line DL5, and the sixth pixel PX6 may be connected to a sixth data line DL6.

Meanwhile, the first pixel PX1, the second pixel PX2, the third pixel PX3, the fourth pixel PX4, the fifth pixel PX5, and the sixth pixel PX6 may emit light beams with different colors. For example, the first pixel PX1 and the fourth pixel PX4 may be red pixels configured to emit red light, the second pixel PX2 and the fifth pixel PX5 may be green pixels configured to emit green light, and the third pixel PX3 and the sixth pixel PX6 may be blue pixels configured to emit blue light. However, the present specification is not limited thereto.

In addition, as described above, the plurality of pixels PX disposed in one area of the display area AA may be connected to the same first selection signal line SSL1 and supplied with the first selection signal Ss, and the plurality of pixels PX may be connected to the same second selection signal line SSL2 and supplied with the second selection signal Ps. For example, the first pixel PX1, the second pixel PX2, the third pixel PX3, the fourth pixel PX4, the fifth pixel PX5, and the sixth pixel PX6 disposed in the first area A1 may each be electrically connected to the first-first selection signal line SSL1a and the second-first selection signal line SSL2a and supplied with the first selection signal Ss and the second selection signal Ps.

Meanwhile, as described with reference to FIG. 9, the first selection signal line SSL1 and the second selection signal line SSL2 may be electrically connected to the first selection signal pattern SSP1 and the second selection signal pattern SSP2, and the first selection signal pattern SSP1 and the second selection signal pattern SSP2 may be electrically connected to the first connection line CLL1 connected to the first signal pad SP1 and the second connection line CLL2 connected to the second signal pad SP2. Therefore, the first selection signal Ss and the second selection signal Ps may be provided to the first selection signal line SSL1 and the second selection signal line SSL2, and the RC delay of the first and second selection signal lines SSL1 and SSL2 may be minimized by the first selection signal patterns SSP1 and second selection signal patterns SSP2 each having a predetermined width.

The data distribution circuit MUX may distribute the data voltage Vdata, which is transmitted by the plurality of data connection lines DLL connected to the plurality of data pads DP, to the plurality of data lines DL in a time division manner. Meanwhile, the plurality of data pads DP may be electrically connected to each of a plurality of output buffers of the data drive circuit DD included in each of the plurality of connection films COF1 and COF2 and receive the data voltage Vdata.

To this end, the data distribution circuit MUX may include a plurality of mux switches. For example, the data distribution circuit MUX may include the mux switches corresponding in number to the pixel columns. Meanwhile, FIG. 10 illustrates six mux switches M1, M2, M3, M4, M5, and M6 corresponding to the six pixels disposed in the row direction.

A first mux switch M1 may electrically connect a first data connection line DLL1, among the plurality of data connection lines DLL, and the first data line DL1 in response to a first distribution control signal MS1. A second mux switch M2 may electrically connect a second data connection line DLL2, among the plurality of data connection lines DLL, and the second data line DL2 in response to the first distribution control signal MS1. A third mux switch M3 may electrically connect a third data connection line DLL3, among the plurality of data connection lines DLL, and the third data line DL3 in response to the first distribution control signal MS1.

In addition, a fourth mux switch M4 may electrically connect the first data connection line DLL1, among the plurality of data connection lines DLL, and the fourth data line DL4 in response to a second distribution control signal MS2. A fifth mux switch M5 may electrically connect the second data connection line DLL2, among the plurality of data connection lines DLL, and the fifth data line DL5 in response to the second distribution control signal MS2. A sixth mux switch M6 may electrically connect the third data connection line DLL3, among the plurality of data connection lines DLL, and the sixth data line DL6 in response to the second distribution control signal MS2.

The first distribution control signal MS1 and the second distribution control signal MS2 may alternately have turn-on levels.

For example, the second distribution control signal MS2 may have a turn-off level in a section in which the first distribution control signal MS1 has a turn-on level. In this case, the first mux switch M1, the second mux switch M2, and the third mux switch M3 may be turned on by the first distribution control signal MS1 at the turn-on level, such that the first data connection line DLL1 connected to a first data pad DP1 may be connected to the first data line DL1, the second data connection line DLL2 connected to a second data pad DP2 may be connected to the second data line DL2, and the third data connection line DLL3 connected to a third data pad DP3 may be connected to the third data line DL3. Therefore, the first pixel PX1, the second pixel PX2, and the third pixel PX3 may receive the data voltage Vdata from the first data line DL1, the second data line DL2, and the third data line DL3.

In addition, the first distribution control signal MS1 may have a turn-off level in a section in which the second distribution control signal MS2 has a turn-on level. In this case, the fourth mux switch M4, the fifth mux switch M5, and the sixth mux switch M6 may be turned on by the second distribution control signal MS2 at the turn-on level, such that the first data connection line DLL1 connected to the first data pad DP1 may be connected to the fourth data line DL4, the second data connection line DLL2 connected to the second data pad DP2 may be connected to the fifth data line DL5, and the third data connection line DLL3 connected to the third data pad DP3 may be connected to the sixth data line DL6. Therefore, the fourth pixel PX4, the fifth pixel PX5, and the sixth pixel PX6 may receive the data voltage Vdata from the fourth data line DL4, the fifth data line DL5, and the sixth data line DL6.

Meanwhile, because the data voltage Vdata provided to the first data connection line DLL1 is provided to the first pixel PX1 and the fourth pixel PX4, the data voltage Vdata may be the data voltage Vdata corresponding to the red light-emitting element. Because the data voltage Vdata provided to the second data connection line DLL2 is provided to the second pixel PX2 and the fifth pixel PX5, the data voltage Vdata may be the data voltage Vdata corresponding to the green light-emitting element. Because the data voltage Vdata provided to the third data connection line DLL3 is provided to the third pixel PX3 and the sixth pixel PX6, the data voltage Vdata may be the data voltage Vdata corresponding to the blue light-emitting element.

As described above, the data distribution circuit MUX may distribute the data voltage Vdata, which is outputted by the output buffers of the data drive circuit DD that are half the number of data lines DL, i.e., the number of pixel columns, to the plurality of data lines DL in a time division manner. Therefore, the number of components included in the data drive circuit DD may be reduced, and the data drive circuit DD may be simplified.

The illumination inspection part AP may check whether the plurality of pixels PX disposed in the display area AA operates abnormally before the shipment of the display device 100. To this end, the illumination inspection part AP may include a first illumination inspection part AP1 configured to provide a first mode illumination inspection signal SSs and a second mode illumination inspection signal SPs, which correspond to the first selection signal Ss and the second selection signal Ps, to the plurality of pixels PX, and a second illumination inspection part AP2 configured to provide a data illumination inspection signal DS, which corresponds to the data voltage Vdata, to the plurality of pixels PX.

The first illumination inspection part AP1 may include a first mode illumination inspection switch SST1 and a second mode illumination inspection switch SST2.

The first mode illumination inspection switch SST1 may electrically connect the first connection line CLL1 to a first mode illumination inspection signal line to which the first mode illumination inspection signal SSs corresponding to the first selection signal Ss is provided in response to a first illumination inspection control signal APS1. In this case, the first mode illumination inspection signal SSs may be provided to the first selection signal line SSL1 via the first connection line CLL1 and the first selection signal pattern SSP1 through the first mode illumination inspection signal line. Therefore, the first mode illumination inspection signal SSs may be provided to the first transistor T1 included in each of the plurality of pixels PX disposed in the display area AA.

The second mode illumination inspection switch SST2 may electrically connect the second connection line CLL2 to a second mode illumination inspection signal line to which the second mode illumination inspection signal SPs corresponding to the second selection signal Ps is provided in response to the first illumination inspection control signal APS1. In this case, the second mode illumination inspection signal SPs may be provided to the second selection signal line SSL2 via the second connection line CLL2 and the second selection signal pattern SSP2 through the second mode illumination inspection signal line. Therefore, the second mode illumination inspection signal SPs may be provided to the second transistor T2 included in each of the plurality of pixels PX disposed in the display area AA.

The first illumination inspection part AP1 may check whether the first transistor T1 and the second transistor T2 of each of the plurality of pixels PX disposed in the display area AA operate abnormally and check whether the first light-emitting element ED1 and the second light-emitting element ED2 emit light before the shipment of the display device 100.

The second illumination inspection part AP2 may include a first data illumination inspection switch LT1, a second data illumination inspection switch LT2, and a third data illumination inspection switch LT3.

The first data illumination inspection switch LT1 may electrically connect the first data connection line DLL1 to a first data illumination inspection signal line to which a first data illumination inspection signal DS1 is provided in response to a second illumination inspection control signal APS2. In this case, the first data illumination inspection signal DS1 may be provided to the first data connection line DLL1.

The second data illumination inspection switch LT2 may electrically connect the second data connection line DLL2 to a second data illumination inspection signal line to which a second data illumination inspection signal DS2 is provided in response to the second illumination inspection control signal APS2. In this case, the second data illumination inspection signal DS2 may be provided to the second data connection line DLL2.

The third data illumination inspection switch LT3 may electrically connect the third data connection line DLL3 to a third data illumination inspection signal line to which a third data illumination inspection signal DS3 is provided in response to the second illumination inspection control signal APS2. In this case, the third data illumination inspection signal DS3 may be provided to the third data connection line DLL3.

In addition, the data distribution circuit MUX may operate as described above and distribute the data illumination inspection signal DS to the plurality of data lines DL in a time division manner during the operation of the second illumination inspection part AP2, e.g., during an illumination inspection period of the display device 100.

For example, the first data connection line DLL1, the second data connection line DLL2, and the third data connection line DLL3 may be respectively connected to the first data line DL1, the second data line DL2, and the third data line DL3 in the section in which the first distribution control signal MS1 has the turn-on level, and the first data connection line DLL1, the second data connection line DLL2, and the third data connection line DLL3 may be respectively connected to the fourth data line DL4, the fifth data line DL5, and the sixth data line DL6 in the section in which the second distribution control signal MS2 has the turn-on level.

Meanwhile, because the first data connection line DLL1 provides the data voltage Vdata to the first pixel PX1 and the fourth pixel PX4, the first data illumination inspection signal DS1, which is provided to the first data connection line DLL1 by the operation of the first data illumination inspection switch LT1, may be substantially identical to the data voltage Vdata corresponding to the red light-emitting element. Because the second data connection line DLL2 provides the data voltage Vdata to the second pixel PX2 and the fifth pixel PX5, the second data illumination inspection signal DS2, which is provided to the second data connection line DLL2 by the operation of the second data illumination inspection switch LT2, may be substantially identical to the data voltage Vdata corresponding to the green light-emitting element. Because the third data connection line DLL3 provides the data voltage Vdata to the third pixel PX3 and the sixth pixel PX6, the third data illumination inspection signal DS3, which is provided to the third data connection line DLL3 by the operation of the third data illumination inspection switch LT3, may be substantially identical to the data voltage Vdata corresponding to the blue light-emitting element.

The second illumination inspection part AP2 may check whether each of the plurality of pixels PX disposed in the display area AA operates abnormally before the shipment of the display device 100.

Meanwhile, as described above, because the illumination inspection pad part, which provides the data illumination inspection signal and the mode illumination inspection signal to the plurality of illumination inspection switches included in the illumination inspection part AP, is removed after the illumination inspection is performed on the display device 100, the illumination inspection part AP does not operate in case that the display device 100 operates after the normal shipment of the display device 100. That is, when the display device 100 operates after the normal shipment of the display device 100, all the plurality of mode illumination inspection switches SST1 and SST2 included in the first illumination inspection part AP1 and the plurality of data illumination inspection switches LT1, LT2, and LT3 included in the second illumination inspection part AP2 may be kept in the turn-on state without operating.

The antistatic part ESD may discharge static electricity applied to the plurality of data lines DL and/or the plurality of selection signal lines SSL1 and SSL2, thereby protecting the plurality of data lines DL and/or the plurality of selection signal lines SSL1 and SSL2 from the static electricity.

For example, the antistatic part ESD may include a plurality of first antistatic parts ESD1 respectively connected to the plurality of connection lines CLL1 and CLL2 to which the selection signal is provided, and a plurality of second antistatic parts ESD2 respectively connected to the plurality of data connection lines DLL.

The plurality of first antistatic parts ESD1 may each include a first antistatic element D1 and a second antistatic element D2 connected in series to each other and disposed between a first voltage line VL1 to which a first voltage VGH at a high level is provided and a second voltage line VL2 to which a second voltage VGL at a low level is provided. For example, the first voltage VGH may have a higher voltage level than the second voltage VGL. For example, the first voltage VGH and the high-potential power voltage VDD may have substantially the same voltage level, and the second voltage VGL and the low-potential power voltage VSS may have substantially the same voltage level. However, the present specification is not limited thereto. According to the embodiment, the second voltage line VL2 to which the second voltage VGL is provided may be electrically connected to the low-potential power line or the second power source pattern PP2 to which the low-potential power voltage VSS is provided. However, the present specification is not limited thereto.

The first antistatic element D1 may be connected between the first voltage line VL1 and the connection line, e.g., the first connection line CLL1 or the second connection line CLL2. For example, the first antistatic element D1 may be a diode. However, the present specification is not limited thereto.

The second antistatic element D2 may be connected between the second voltage line VL2 and the connection line, e.g., the first connection line CLL1 or the second connection line CLL2. For example, the second antistatic element D2 may be a diode. However, the present specification is not limited thereto.

Therefore, the first antistatic element D1 and the second antistatic element D2 may protect the first selection signal line SSL1 connected to the first connection line CLL1 and the second selection signal line SSL2 connected to the second connection line CLL2 from static electricity by discharging the static electricity, which is applied to the connection line, e.g., the first connection line CLL1 and the second connection line CLL2 to which the selection signal is provided, to the second voltage line VL2 to which the second voltage VGL at a low level is provided.

The plurality of second antistatic parts ESD2 may each include a third antistatic element D3 and a fourth antistatic element D4 connected in series to each other and disposed between the first voltage line VL1 to which the first voltage VGH at a high level is provided and the second voltage line VL2 to which the second voltage VGL at a low level is provided.

The third antistatic element D3 may be connected between the first voltage line VL1 and any one data connection line among the plurality of data connection lines DLL, e.g., the first data connection line DLL1, the second data connection line DLL2, or the third data connection line DLL3. For example, the third antistatic element D3 may be a diode. However, the present specification is not limited thereto.

The fourth antistatic element D4 may be connected between the second voltage line VL2 and any one data connection line among the plurality of data connection lines DLL, e.g., the first data connection line DLL1, the second data connection line DLL2, or the third data connection line DLL3. For example, the fourth antistatic element D4 may be a diode. However, the present specification is not limited thereto.

Therefore, the third antistatic element D3 and the fourth antistatic element D4 may protect the plurality of data lines DL connected to the plurality of data connection lines DLL from static electricity by discharging the static electricity, which is applied to the plurality of data connection lines DLL to which the data voltage Vdata is provided, to the second voltage line VL2 to which the second voltage VGL at a low level is provided.

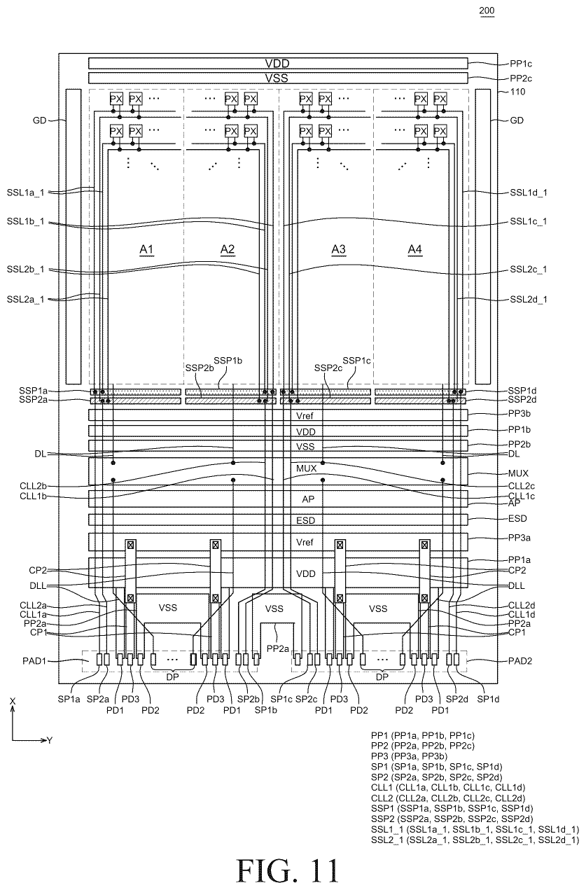

FIG. 11 is a top plan view of the display device according to another embodiment of the present specification.

Meanwhile, FIG. 11 illustrates a modified embodiment of the embodiment in FIG. 9 in relation to a connection relationship between a first selection signal line SSL1_1 and a second selection signal line SSL2_1. Therefore, in order to avoid a repeated description, the description will be focused on differences from the above-mentioned embodiment with reference to FIG. 11.

With reference to FIG. 11, a display device 200 may include the substrate 110, the gate drive circuit GD, the plurality of pad parts PAD1 and PAD2, the plurality of power source patterns PP1, PP2, and PP3, the data distribution circuit MUX, the antistatic part ESD, the illumination inspection part AP, the first selection signal pattern SSP1, the second selection signal pattern SSP2, and various types of signal lines.

The plurality of first selection signal lines SSL1_1 and the plurality of second selection signal lines SSL2_1 may each be disposed to extend from the non-display area NA to the display area AA.

The plurality of first selection signal lines SSL1_1 may include a plurality of first-first selection signal lines SSL1a_1 electrically connected to the first-first selection signal pattern SSP1a, a plurality of first-second selection signal lines SSL1b_1 electrically connected to the first-second selection signal pattern SSP1b, a plurality of first-third selection signal lines SSL1c_1 electrically connected to the first-third selection signal pattern SSP1c, and a plurality of first-fourth selection signal lines SSL1d_1 electrically connected to the first-fourth selection signal pattern SSP1d.

For example, one end of each of the plurality of first-first selection signal lines SSL1a_1 may be connected to the first-first selection signal pattern SSP1a to which the first selection signal Ss provided to the first area A1 is provided. In addition, the plurality of first-first selection signal lines SSL1a_1 may extend in the first direction X and the second direction Y, be connected to the plurality of pixels PX disposed in the plurality of pixel rows in the first area A1, and supply the first selection signal Ss. Therefore, the number of first-first selection signal lines SSL1a_1 may be equal to the number of pixel rows of the display area AA. In this case, because all the plurality of first-first selection signal lines SSL1a_1 are connected to the first-first selection signal pattern SSP1a to which the first selection signal Ss provided to the first area A1 is provided, the same first selection signal Ss may be provided to the plurality of pixels PX disposed in the first area A1.

In addition, one end of each of the plurality of first-second selection signal lines SSL1b_1 may be connected to the first-second selection signal pattern SSP1b to which the first selection signal Ss provided to the second area A2 is provided. In addition, the plurality of first-second selection signal lines SSL1b_1 may extend in the first direction X and the second direction Y, be connected to the plurality of pixels PX disposed in the plurality of pixel rows in the second area A2, and supply the first selection signal Ss. Therefore, the number of first-second selection signal lines SSL1b_1 may be equal to the number of pixel rows of the display area AA. In this case, because all the plurality of first-second selection signal lines SSL1b_1 are connected to the first-second selection signal pattern SSP1b to which the first selection signal Ss provided to the second area A2 is provided, the same first selection signal Ss may be provided to the plurality of pixels PX disposed in the first area A1.

In addition, one end of each of the plurality of first-third selection signal lines SSL1c_1 may be connected to the first-third selection signal pattern SSP1c to which the first selection signal Ss provided to the third area A3 is provided. In addition, the plurality of first-third selection signal lines SSL1c_1 may extend in the first direction X and the second direction Y, be connected to the plurality of pixels PX disposed in the plurality of pixel rows in the third area A3, and supply the first selection signal Ss. Therefore, the number of first-third selection signal lines SSL1c_1 may be equal to the number of pixel rows of the display area AA. In this case, because all the plurality of first-third selection signal lines SSL1c_1 are connected to the first-third selection signal pattern SSP1c to which the first selection signal Ss provided to the third area A3 is provided, the same first selection signal Ss may be provided to the plurality of pixels PX disposed in the third area A3.

In addition, one end of each of the plurality of first-fourth selection signal lines SSLId_1 may be connected to the first-fourth selection signal pattern SSP1d to which the first selection signal Ss provided to the fourth area A4 is provided. In addition, the plurality of first-fourth selection signal lines SSL1d_1 may extend in the first direction X and the second direction Y, be connected to the plurality of pixels PX disposed in the plurality of pixel rows in the fourth area A4, and supply the first selection signal Ss. Therefore, the number of first-fourth selection signal lines SSL1d_1 may be equal to the number of pixel rows of the display area AA. In this case, because all the plurality of first-fourth selection signal lines SSL1d_1 are connected to the first-fourth selection signal pattern SSP1d to which the first selection signal Ss provided to the fourth area A4 is provided, the same first selection signal Ss may be provided to the plurality of pixels PX disposed in the fourth area A4.

The plurality of second selection signal lines SSL2_1 may include a plurality of second-first selection signal lines SSL2a_1 electrically connected to the second-first selection signal pattern SSP2a, a plurality of second-second selection signal lines SSL2b_1 electrically connected to the second-second selection signal pattern SSP2b, a plurality of second-third selection signal lines SSL2c_1 electrically connected to the second-third selection signal pattern SSP2c, and a plurality of second-fourth selection signal lines SSL2d_1 electrically connected to the second-fourth selection signal pattern SSP2d.

For example, one end of each of the plurality of second-first selection signal lines SSL2a_1 may be connected to the second-first selection signal pattern SSP2a to which the second selection signal Ps provided to the first area A1 is provided. In addition, the plurality of second-first selection signal lines SSL2a_1 may extend in the first direction X and the second direction Y, connected to the plurality of pixels PX disposed in the plurality of pixel rows in the first area A1, and supply the second selection signal Ps. Therefore, the number of second-first selection signal lines SSL2a_1 may be equal to the number of pixel rows of the display area AA. In this case, because all the plurality of second-first selection signal lines SSL2a_1 are connected to the second-first selection signal pattern SSP2a to which the second selection signal Ps provided to the first area A1 is provided, the same second selection signal Ps may be provided to the plurality of pixels PX disposed in the first area A1.

In addition, one end of each of the plurality of second-second selection signal lines SSL2b_1 may be connected to the second-second selection signal pattern SSP2b to which the second selection signal Ps provided to the second area A2 is provided. In addition, the plurality of second-second selection signal lines SSL2b_1 may extend in the first direction X and the second direction Y, connected to the plurality of pixels PX disposed in the plurality of pixel rows in the second area A2, and supply the second selection signal Ps. Therefore, the number of second-second selection signal lines SSL2b_1 may be equal to the number of pixel rows of the display area AA. In this case, because all the plurality of second-second selection signal lines SSL2b_1 are connected to the second-second selection signal pattern SSP2b to which the second selection signal Ps provided to the second area A2 is provided, the same second selection signal Ps may be provided to the plurality of pixels PX disposed in the first area A1.

In addition, one end of each of the plurality of second-third selection signal lines SSL2c_1 may be connected to the second-third selection signal pattern SSP2c to which the second selection signal Ps provided to the third area A3 is provided. In addition, the plurality of second-third selection signal lines SSL2c_1 may extend in the first direction X and the second direction Y, connected to the plurality of pixels PX disposed in the plurality of pixel rows in the third area A3, and supply the second selection signal Ps. Therefore, the number of second-third selection signal lines SSL2c_1 may be equal to the number of pixel rows of the display area AA. In this case, because all the plurality of second-third selection signal lines SSL2c_1 are connected to the second-third selection signal pattern SSP2c to which the second selection signal Ps provided to the third area A3 is provided, the same second selection signal Ps may be provided to the plurality of pixels PX disposed in the third area A3.

In addition, one end of each of the plurality of second-fourth selection signal lines SSL2d_1 may be connected to the second-fourth selection signal pattern SSP2d to which the second selection signal Ps provided to the fourth area A4 is provided. In addition, the plurality of second-fourth selection signal lines SSL2d_1 may extend in the first direction X and the second direction Y, connected to the plurality of pixels PX disposed in the plurality of pixel rows in the fourth area A4, and supply the second selection signal Ps. Therefore, the number of second-fourth selection signal lines SSL2d_1 may be equal to the number of pixel rows of the display area AA. In this case, because all the plurality of second-fourth selection signal lines SSL2d_1 are connected to the second-fourth selection signal pattern SSP2d to which the second selection signal Ps provided to the fourth area A4 is provided, the same second selection signal Ps may be provided to the plurality of pixels PX disposed in the fourth area A4.

As described above, the first selection signal Ss and the second selection signal Ps may be independently provided to the plurality of areas A1, A2, A3, and A4 of the display area AA, such that the drive modes of the plurality of areas A1, A2, A3, and A4 may be controlled independently.

In addition, in comparison with a case in which a single selection signal line, e.g., a single first selection signal line and a single second selection signal line for providing selection signals are disposed in the plurality of areas A1, A2, A3, and A4, the display device 200 according to the embodiment of the present specification includes the plurality of first selection signal lines SSL1_1 configured to provide the first selection signal Ss to different lines for each of the pixel rows in each of the plurality of areas A1, A2, A3, and A4, and the plurality of second selection signal lines SSL2_1 configured to provide the second selection signal Ps to different lines for each of the pixel rows in each of the plurality of areas A1, A2, A3, and A4, such that the resistance of the plurality of selection signal lines SSL1_1 and SSL2_1 may be further reduced, and the RC delay, which may occur on the plurality of selection signal lines SSL1 and SSL2, may be more effectively improved.

The exemplary embodiments of the present disclosure can also be described as follows:

According to an aspect of the present disclosure, there is provided a display device. The display device comprises a substrate comprising a display area and a non-display area disposed to surround the display area; a plurality of pixels disposed in the display area of the substrate; a pad part disposed in the non-display area of the substrate and supplied with a selection signal; a connection line disposed in the non-display area of the substrate, extending in a first direction, and connected to the pad part; a selection signal pattern disposed in the non-display area of the substrate, extending in a second direction different from the first direction, and connected to the connection line; and a selection signal line disposed to extend from the non-display area to the display area of the substrate, connected to the selection signal pattern, and configured to provide the selection signal, which is supplied from the pad part, to the plurality of pixels.

The selection signal line may comprise a main line extending in the first direction; and a plurality of auxiliary lines branching off from the main line and extending in the second direction.

The plurality of auxiliary lines may be disposed for each of a plurality of pixel rows in the display area.

A width of the selection signal pattern in the first direction may be larger than a width of the selection signal line.

The selection signal pattern may include a metallic material.

The plurality of pixels each may comprise a first transistor; a first light-emitting element configured to emit light by a first drive current supplied from the first transistor; a second transistor; and a second light-emitting element configured to emit light by a second drive current supplied from the second transistor and emit light with the same color as the light emitted from the first light-emitting element.

The selection signal line may comprise a first selection signal line configured to provide a first selection signal to the first transistor; and a second selection signal line configured to provide a second selection signal to the second transistor.

The selection signal pattern may comprise a first selection signal pattern connected to the first selection signal line; and a second selection signal pattern connected to the second selection signal line.

The first selection signal pattern and the second selection signal pattern may be disposed adjacent to each other in the first direction.

The connection line may comprise a first connection line configured to receive the first selection signal from the pad part and connected to the first selection signal pattern; and a second connection line configured to receive the second selection signal from the pad part and connected to the second selection signal pattern.

The plurality of pixels each may further comprise a first optical member configured to refract light from the first light-emitting element; and a second optical member configured to refract light from the second light-emitting element and having a shape different from a shape of the first optical member.

The display device may further comprise an illumination inspection part disposed in the non-display area and connected to the connection line, wherein the illumination inspection part may comprise at least one mode illumination inspection switch configured to provide a mode illumination inspection signal to the connection line in response to an illumination inspection control signal.

The display device may further comprise an antistatic part disposed in the non-display area and connected to the connection line, wherein the antistatic part may comprise a first antistatic element and a second antistatic element connected in series between a first voltage line to which a first voltage is provided and a second voltage line to which a second voltage lower than the first voltage is provided.

According to another aspect of the present disclosure, there is provided a display device. The display device comprises a substrate comprising a display area and a non-display area disposed to surround the display area; a plurality of pixels disposed in the display area of the substrate; a pad part disposed in the non-display area of the substrate and supplied with a selection signal; a connection line disposed in the non-display area of the substrate, extending in a first direction, and connected to the pad part; a selection signal pattern disposed in the non-display area of the substrate, extending in a second direction different from the first direction, and connected to the connection line; and a plurality of selection signal lines disposed to extend from the non-display area to the display area of the substrate, connected to the selection signal pattern, and configured to provide the selection signal, which is supplied from the pad part, to the plurality of pixels, wherein the plurality of selection signal lines is disposed for each pixel row of the display area.

The plurality of selection signal lines may extend in the first direction and the second direction.

A width of the selection signal pattern in the first direction may be larger than a width of each of the plurality of selection signal lines.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate comprising a display area and a non-display area that surrounds the display area;
a plurality of pixels in the display area of the substrate;
a pad part in the non-display area of the substrate, the pad part supplied with a selection signal;
a connection line in the non-display area of the substrate, the connection line extending in a first direction and connected to the pad part;
a selection signal pattern in the non-display area of the substrate, the selection signal pattern extending in a second direction that is different from the first direction and connected to the connection line; and
a selection signal line that extends from the non-display area to the display area of the substrate, the selection signal connected to the selection signal pattern and configured to provide the selection signal, which is supplied from the pad part, to the plurality of pixels.

2. The display device of claim 1, wherein the selection signal line comprises:
a main line extending in the first direction; and
a plurality of auxiliary lines branching off from the main line and extending in the second direction.

3. The display device of claim 2, wherein the plurality of auxiliary lines are disposed for each of a plurality of pixel rows in the display area.

4. The display device of claim 1, wherein a width of the selection signal pattern in the first direction is larger than a width of the selection signal line.

5. The display device of claim 1, wherein the selection signal pattern includes a metallic material.

6. The display device of claim 1, wherein each of the plurality of pixels comprises:
a first transistor;
a first light-emitting element configured to emit light by a first drive current supplied from the first transistor;
a second transistor; and
a second light-emitting element configured to emit light by a second drive current supplied from the second transistor,
wherein the light emitted by the second light-emitting element is a same color as the light emitted from the first light-emitting element.

7. The display device of claim 6, wherein the selection signal line comprises:
a first selection signal line configured to provide a first selection signal to the first transistor; and
a second selection signal line configured to provide a second selection signal to the second transistor.

8. The display device of claim 7, wherein the selection signal pattern comprises:
a first selection signal pattern connected to the first selection signal line; and
a second selection signal pattern connected to the second selection signal line.

9. The display device of claim 8, wherein the first selection signal pattern and the second selection signal pattern are adjacent to each other in the first direction.

10. The display device of claim 8, wherein the connection line comprises:
a first connection line configured to receive the first selection signal from the pad part and connected to the first selection signal pattern; and
a second connection line configured to receive the second selection signal from the pad part and connected to the second selection signal pattern.

11. The display device of claim 6, wherein each of the plurality of pixels further comprises:
a first optical member configured to refract light from the first light-emitting element; and
a second optical member configured to refract light from the second light-emitting element, the second optical member having a shape different from a shape of the first optical member.

12. The display device of claim 1, further comprising:
an illumination inspection part in the non-display area, the illumination inspection part connected to the connection line,
wherein the illumination inspection part comprises at least one mode illumination inspection switch configured to provide a mode illumination inspection signal to the connection line in response to an illumination inspection control signal.

13. The display device of claim 1, further comprising:
an antistatic part in the non-display area, the antistatic part connected to the connection line,
wherein the antistatic part comprises a first antistatic element and a second antistatic element connected in series between a first voltage line to which a first voltage is provided and a second voltage line to which a second voltage lower than the first voltage is provided.

14. A display device comprising:
a substrate comprising a display area and a non-display area that surrounds the display area;
a plurality of pixels in the display area of the substrate;
a pad part in the non-display area of the substrate, the pad part supplied with a selection signal;
a connection line in the non-display area of the substrate, the connection line extending in a first direction and connected to the pad part;
a selection signal pattern in the non-display area of the substrate, the selection signal pattern extending in a second direction that is different from the first direction and connected to the connection line; and
a plurality of selection signal lines that extend from the non-display area to the display area of the substrate, the plurality of selection signal lines connected to the selection signal pattern and configured to provide the selection signal, which is supplied from the pad part, to the plurality of pixels,
wherein the plurality of selection signal lines are disposed for each pixel row of the display area.

15. The display device of claim 14, wherein the plurality of selection signal lines extend in the first direction and the second direction.

16. The display device of claim 14, wherein a width of the selection signal pattern in the first direction is larger than a width of each of the plurality of selection signal lines.

17. A display device comprising:
a display area and a non-display area that surrounds the display area,
wherein the display area comprises a plurality of pixels;
wherein each of the plurality of pixels comprises:
a first light-emitting element emitting light of a first color,
a first optical member on the first light-emitting element, the first optical member providing a first viewing angle range,
a first transistor from which a first drive current for emitting light is supplied to the first light-emitting element,
a second light-emitting element emitting light of the first color,
a second optical member on the second light-emitting element, the second optical member providing a second viewing angle range that is wider than the first viewing angle range, and
a second transistor from which a second drive current for emitting light is supplied to the second light-emitting element, and
wherein the first transistor and the second transistor are controlled by different selection signal lines.

18. The display device of claim 17, wherein the display area comprises a plurality of sub display areas arranged along a second direction;
the non-display area comprises a plurality of selection signal pattern pairs corresponding to the plurality of sub display areas;
a first selection signal pattern and a second selection signal pattern in each of the plurality of selection signal pattern pairs are separated from each other along a first direction perpendicular to the second direction; and
for a first selected signal pattern pair of the plurality of selection signal pattern pairs and a pixel in a first sub display area corresponding to the first selected signal pattern pair:
a first selection signal pattern of the first selected signal pattern pair is configured to receive a first selection signal and be connected to a first transistor of the pixel, via a first selection signal line, to control, based on the first selection signal, a first light-emitting element of the pixel whether to emit light, and
a second selection signal pattern of the first selected signal pattern pair is configured to receive a second selection signal and be connected to a second transistor of the pixel to control, via a first selection signal line, based on the second selection signal, a second light-emitting element of the pixel whether to emit light.

19. A display device comprising:
a display area and a non-display area that surrounds the display area;
a plurality of pixels in the display area;
a pad part in the non-display area, the pad part receiving a selection signal;
a selection signal pattern in the non-display area and connected with the pad part; and
a selection signal line connected to the selection signal pattern and the plurality of pixels, the selection signal line providing the selection signal to the plurality of pixels.
